(19) United States
(12) Patent Application Publication
(10) Pub. No.: US 2026/0324109 A1
(43) Pub. Date: Oct. 15, 2026

(54) IMAGING DEVICE

(71) Applicant: Panasonic Intellectual Property Management Co., Ltd., Osaka (JP)

(72) Inventor: YOSHIHIRO SATO, Osaka (JP)

(21) Appl. No.: 19/690,116

(22) Filed: May 28, 2026

Related U.S. Application Data
(63) Continuation of application No. PCT/JP2024/036758, filed on Oct. 16, 2024.

(30) Foreign Application Priority Data
Dec. 26, 2023 (JP) 2023-219319

(51) Int. Cl. H10F 39/00; H04N 25/62

(52) U.S. Cl. CPC H10F 39/8037; H04N 25/62; H10F 39/811; H10F 39/8027

(57) ABSTRACT

An imaging device includes a photoelectric converter that converts light into electric charge, a semiconductor substrate including a first impurity region and a second impurity region, and a first plug that is connected to the first impurity region and that includes a silicide region. Either the first impurity region or the second impurity region is a charge accumulation region that is electrically connected to the photoelectric converter. The semiconductor substrate includes, in a position that faces the silicide region across the first impurity region, a third impurity region containing a group 14 element other than silicon.

### BACKGROUND

### 1. Technical Field

The present disclosure relates to an imaging device.

### 2. Description of the Related Art

CCD (charge-coupled device) image sensors and CMOS (complementary metal-oxide semiconductor) image sensors are widely used in digital cameras or other devices. These image sensors have, for example, a photodiode formed on a semiconductor substrate or a photoelectric conversion layer formed above a semiconductor substrate.

For example, Japanese Unexamined Patent Application Publication No. 2019-102494 discloses a solid-state imaging device including a photoelectric converter formed on a semiconductor substrate, a transistor formed on the semiconductor substrate, and a gettering region in the semiconductor substrate. Further, Japanese Unexamined Patent Application Publication No. 2019-102494 also discloses that a source and drain of the transistor formed on the semiconductor substrate contain silicide.

### SUMMARY

The imaging device is required to reduce a leak current in the semiconductor substrate to reduce noise.

One non-limiting and exemplary embodiment provides an imaging device that can reduce a leak current.

In one general aspect, the techniques disclosed here feature an imaging device including a photoelectric converter that converts light into electric charge, a semiconductor substrate including a first impurity region and a second impurity region, and a first plug that is connected to the first impurity region and that includes a silicide region. Either the first impurity region or the second impurity region is a charge accumulation region that is electrically connected to the photoelectric converter. The semiconductor substrate includes, in a position that faces the silicide region across the first impurity region, a third impurity region containing a group 14 element other than silicon.

The present disclosure makes it possible to provide an imaging device that can reduce a leak current.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram showing a configuration of an imaging device according to Embodiment 1;

FIG. 2 is a diagram showing a circuit configuration of the imaging device according to Embodiment 1;

FIG. 3 is a plan view showing a layout of the inside of a pixel according to Embodiment 1;

FIG. 4 is a schematic cross-sectional view of a device structure of the pixel according to Embodiment 1;

FIG. 5A is a diagram showing a distribution of concentration of nickel in a contact plug and an impurity region;

FIG. 5B is a diagram showing a distribution of impurity concentration in an area near a gettering layer in a semiconductor substrate;

FIG. 6 is a diagram showing a relationship between a ratio of concentration of nickel and carbon and a dark current;

FIG. 7 is a diagram showing a relationship between a ratio of concentration of nickel and oxygen and a dark current;

FIG. 8 is a schematic cross-sectional view of a device structure of an imaging device according to a modification of Embodiment 1;

FIG. 9 is a schematic cross-sectional view of a device structure of a pixel of an imaging device according to Embodiment 2;

FIG. 10 is a schematic cross-sectional view of a device structure of an imaging device according to Embodiment 3;

FIG. 11 is a schematic cross-sectional view of a device structure of an imaging device according to Embodiment 4;

FIG. 12 is a diagram showing a configuration of an imaging device according to Embodiment 5;

FIG. 13 is a schematic cross-sectional view of a device structure of the imaging device according to Embodiment 5;

FIG. 14 is a plan view of a silicide region as seen in a plan view in a substrate potential supply region; and

FIG. 15 is a block diagram showing an example of a configuration of a camera system according to Embodiment 5.

### DETAILED DESCRIPTIONS

### Underlying Knowledge Forming Basis of the Present Disclosure

Prior to a specific description of embodiments of the present disclosure, an underlying knowledge forming the basis of the present disclosure as found out by the inventor is described.

There has been known a technology with which to form a silicide region in an area of contact between a metal and a semiconductor to reduce the contact resistance of the area of contact. In an imaging device, for example, forming a silicide region in an electrical connecting portion of a transistor for driving is effective in improving the driving capability of the transistor. Meanwhile, forming a silicide region causes a metal for forming the silicide region to diffuse as a metallic impurity into a semiconductor substrate, making it likely that a leak current is generated at a p-n junction in the semiconductor substrate. For example, in the imaging device, a leak current at a p-n junction in an impurity region that functions as a charge accumulation region in the semiconductor substrate becomes a dark current that flows even during a dark period, leading to an increase in noise. Unless otherwise noted, the term “leak current in a semiconductor substrate” herein refers to a leak current at a p-n junction in a semiconductor substrate.

The inventor has focused on the fact that forming within a semiconductor substrate a gettering layer containing an impurity element is effective in reducing a metallic impurity in a case where a silicide region is formed. The gettering layer is an impurity region formed within the semiconductor substrate to getter the metallic impurity. Further, the inventor has also found out that the diffusion of the impurity element of the gettering layer for gettering the metallic impurity may cause an increase in leak current. Thus, controlling the effect of the impurity element diffusing from the gettering layer is effective in effectively reducing a leak current in the semiconductor substrate.

The present disclosure has been made on the basis of the inventor's points of view and findings such as these and provides an imaging device that can reduce a leak current even in a case where a silicide region is provided in the imaging device.

### Brief Overview of the Present Disclosure

As a brief overview of the present disclosure, the following shows examples of an imaging device according to the present disclosure.

For example, an imaging device according to a first aspect of the present disclosure includes a photoelectric converter that converts light into electric charge, a semiconductor substrate including a first impurity region and a second impurity region, and a first plug that is connected to the first impurity region and that includes a silicide region. Either the first impurity region or the second impurity region is a charge accumulation region that is electrically connected to the photoelectric converter. The semiconductor substrate includes, in a position that faces the silicide region across the first impurity region, a third impurity region containing a group 14 element other than silicon.

According to this configuration, the first plug, which is connected to the first impurity region, includes the silicide region. This makes it possible to reduce contact resistance with a metal, bringing about improvement in conductance in making an electrical connection via the first impurity region. Further, the silicide region is present in the first plug. This makes it possible to, even if the first impurity region is not directly silicidated, bring about improvement in conductance in making an electrical connection via the first impurity region. This makes it possible to reduce the concentration of a metallic impurity in the first impurity region. Furthermore, a metallic impurity diffusing from the silicide region of the first plug is gettered by the group 14 element other than silicon in the third impurity region. This makes it possible to reduce the generation of a leak current within the semiconductor substrate by the metallic impurity.

Further, for example, a second aspect of the present disclosure may be directed to the imaging device according to the first aspect, wherein the first impurity region is the charge accumulation region.

This makes it possible to, while bringing about improvement in conductance in making an electrical connection to the charge accumulation region, reduce a leak current in the charge accumulation region that may become a dark current.

Further, for example, a third aspect of the present disclosure may be directed to the imaging device according to the first aspect, further including a second plug that is connected to the second impurity region and that includes no silicide region, wherein the second impurity region is a charge accumulation region.

According to this configuration, the second plug, which includes no silicide region, is connected to the charge accumulation region. This makes it possible to suppress the diffusion of the metallic impurity into the charge accumulation region, making it possible to reduce a leak current in the charge accumulation region that may become a dark current.

Further, for example, a fourth aspect of the present disclosure may be directed to the imaging device according to any one of the first to third aspects, wherein a distance between the first impurity region and the third impurity region is longer than a distance between the silicide region and the first impurity region.

This makes it possible to reduce the effect brought about by the group 14 element other than silicon in the third impurity region diffusing into the first impurity region, making it possible to reduce a leak current in the first impurity region attributed to the group 14 element other than silicon. Further, even in a case where the distance between the first impurity region and the third impurity region is long, the metallic impurity of the silicide region reaches the third impurity region and is gettered, as the metallic impurity of the silicide region is much higher in diffusion coefficient than the group 14 element other than silicon and likely to diffuse.

Further, for example, a fifth aspect of the present disclosure may be directed to the imaging device according to any one of the first to fourth aspects, wherein the third impurity region contains carbon, and the relation 1<A/B<400000 is satisfied, where A represents a concentration of a metallic element of metallic silicide in the silicide region in units of atoms/cm³; and B represents a concentration of carbon in the third impurity region in units of atoms/cm³.

Further, for example, a sixth aspect of the present disclosure may be directed to the imaging device according to the fifth aspect, wherein the relation 10<A/B<7000 is satisfied.

This concentration ratio of A/B makes it possible to, while enhancing the effect of gettering the metallic element in the silicide region by carbon of the third impurity region, inhibit carbon from being excessively diffused to getter the metallic element, making it possible to further reduce a leak current in the semiconductor substrate.

Further, for example, a seventh aspect of the present disclosure may be directed to the imaging device according to any one of the first to sixth aspects, wherein the third impurity region contains the group 14 element and oxygen, and the relation 2<A/C<10000 is satisfied, where A represents a concentration of a metallic element of metallic silicide in the silicide region in units of atoms/cm³; and C represents a concentration of oxygen in the third impurity region in units of atoms/cm³.

Further, for example, an eighth aspect of the present disclosure may be directed to the imaging device according to the seventh aspect, wherein the relation 40<A/C<200 is satisfied.

This concentration ratio of A/C makes it possible to, while enhancing the effect of gettering the metallic element in the silicide region by oxygen of the third impurity region, inhibit oxygen from being excessively diffused to getter the metallic element, making it possible to further reduce a leak current in the semiconductor substrate.

Further, for example, a ninth aspect of the present disclosure may be directed to the imaging device according to any one of the first to eighth aspects wherein the semiconductor substrate includes a base substrate and an epitaxial layer on top of the base substrate, the first impurity region and the second impurity region are located within the epitaxial layer, and the third impurity region is located within the base substrate.

According to this configuration, the third impurity region is located within the base substrate. This makes it possible to reduce the effect brought about by the group 14 element other than silicon in the third impurity region diffusing into the first impurity region and the second impurity region, which are located within the epitaxial layer, making it possible to reduce a leak current in the first impurity region and the second impurity region. Further, the first impurity region and the second impurity region are provided not in the base substrate, whose crystallinity tends to be brought into disorder by the third impurity region being provided, but in the epitaxial layer, whose crystallinity is high.

Further, for example, a tenth aspect of the present disclosure may be directed to the imaging device according to any one of the first to fourth aspects, wherein the semiconductor substrate includes an imaging region where a plurality of pixels each including the photoelectric converter, the first impurity region, the second impurity region, and a first plug are arranged, and the third impurity region is continuously placed all over the imaging region.

Further, for example, an eleventh aspect of the present disclosure may be directed to the imaging device according to any one of the first to fourth aspects, wherein the third impurity region is continuously placed all over the semiconductor substrate.

Further, for example, an imaging device according to a twelfth aspect of the present disclosure includes a photoelectric converter that converts light into electric charge, a semiconductor substrate including a first impurity region that is electrically connected to the photoelectric converter and a second impurity region that is placed in a position different from that of the first impurity region in a plan view and that includes a silicide region, and a plug that is connected to the silicide region of the second impurity region. The semiconductor substrate includes, in a position that faces the plug across the second impurity region, a third impurity region containing a group 14 element other than silicon. The second impurity region and the third impurity region are separate from each other. A distance between the silicide region and the third impurity region is shorter than a distance between the silicide region and the first impurity region.

According to this configuration, the second impurity region is connected to the plug in the silicide region. This makes it possible to reduce contact resistance between the second impurity region and the plug, bringing about improvement in conductance in making an electrical connection via the second impurity region. Further, the third impurity region is provided in a position closer to the silicide region than is the first impurity region. This makes it likely that a metallic impurity diffusing from the silicide region is gettered by the group 14 element other than silicon in the third impurity region before reaching the first impurity region. This makes it possible to reduce a leak current in the first impurity region.

The following describes embodiments of the present disclosure in concrete terms with reference to the drawings. It should be noted that the embodiments to be described below each illustrate a comprehensive and specific example. The numerical values, shapes, materials, constituent elements, placement and topology of constituent elements, steps, orders of steps, or other features that are shown in the following embodiments are just a few examples and are not intended to limit the present disclosure. Various aspects described herein can be combined with each other unless a contradiction arises. Further, those of the constituent elements in the following embodiments which are not recited in an independent claim are described as optional constituent elements. Further, in the drawings, constituent elements having substantially the same functions are given common reference signs, and a repeated description may be omitted or simplified.

Further, the various elements shown in the drawings are merely schematically shown for understanding of the present disclosure, and dimensional ratios and appearances can be different from those of actual elements. That is, the drawings are schematic views and are not necessarily strict illustrations. Accordingly, for example, the drawings are not necessarily to scale.

Further, terms used herein to show the way in which elements are interrelated, such as “parallel” or “coincide”, terms used herein to show the shape of an element, such as “circular” or “rectangular”, and ranges of numerical values used herein are not expressions that represent only exact meanings but expressions that are meant to also encompass substantially equivalent ranges, e.g. differences of approximately several percent.

Further, the terms “above” and “below” used herein do not refer to an upward direction (upward in a vertical direction) and a downward direction (downward in a vertical direction) in absolute space recognition, but are used as terms that are defined by a relative positional relationship on the basis of an order of stacking in a stack configuration. Specifically, the term “above” refers to an optical incidence side of an imaging device, and the term “below” refers to a side of the imaging device that faces away from the optical incidence side. The same applies to an “upper surface” and a lower surface” of each member. That is, the term “upper surface” refers to an optical incidence surface of the imaging device, and the term “lower surface” refers to a surface that faces away from the optical incidence surface. It should be noted that terms such as “above”, “below”, “upper surface”, and “lower surface” are used solely to designate the mutual placement of members and are not intended to limit the attitude of the imaging device during use. Further, the terms “above” and “below” are applied not only in a case where two constituent elements are placed at a spacing from each other and another constituent element is present between the two constituent elements, but also in a case where two constituent elements are placed in close contact with each other and the two constituent elements touch each other. Further, the term “plan view” herein refers to a view from a direction perpendicular to an upper surface of a semiconductor substrate (in other words, a thickness direction of the semiconductor substrate).

Further, the clause “a transistor is placed on a surface of the semiconductor substrate” means that a gate and source of the transistor and a drain of the transistor are placed with the surface interposed therebetween.

Further, not only visible light but also invisible light such as ultraviolet light and near-infrared light are herein expressed as “light” for convenience.

### Embodiment 1

The following describes an imaging device according to Embodiment 1.

### Configuration

First, a configuration of an imaging device according to the present embodiment is described.

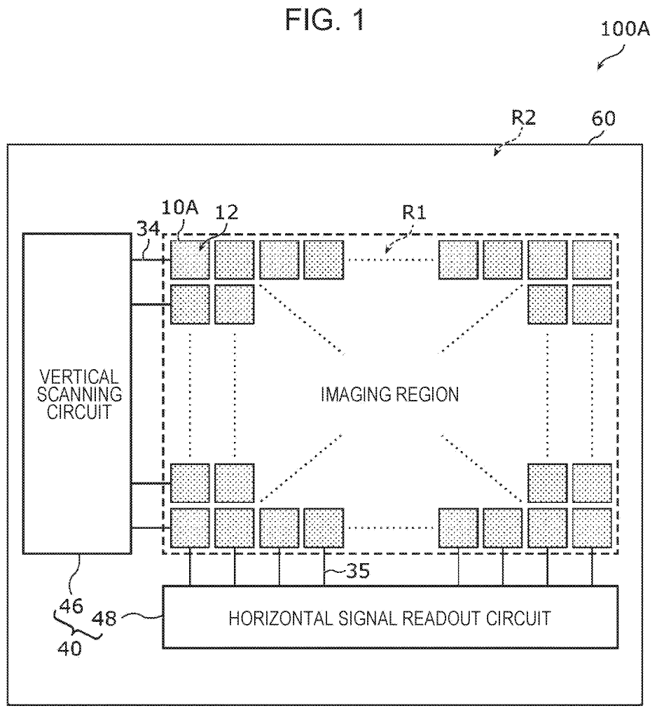

FIG. 1 is a diagram showing a configuration of an imaging device 100A according to the present embodiment. As shown in FIG. 1, the imaging device 100A according to the present embodiment includes a plurality of pixels 10A formed on a semiconductor substrate 60 and a peripheral circuit 40 formed on the semiconductor substrate 60. Each pixel 10A includes a photoelectric converter 12 placed above the semiconductor substrate 60. Such an imaging device 100A including a photoelectric converter 12 placed above the semiconductor substrate 60 is also called “stacked imaging device”.

In the example shown in FIG. 1, the pixels 10A are arranged in a matrix having m rows and n columns. Note here that m and n are integers greater than or equal to 2. The pixels 10A form an imaging region R1 by being, for example, two-dimensionally arrayed on the semiconductor substrate 60. As mentioned above, each pixel 10A includes a photoelectric converter 12 placed above the semiconductor substrate 60. Therefore, the imaging region R1 is defined as a region of the semiconductor substrate 60 covered by the photoelectric converters 12. Although, for ease of explanation, FIG. 1 shows the photoelectric converter 12 of each pixel 10A as being spatially separate from the photoelectric converter 12 of the other pixel 10A, the photoelectric converters 12 of the plurality of pixels 10A can be arranged on top of the semiconductor substrate 60 with no spacings therebetween.

The number and placement of the pixels 10A are not limited to the illustrated example. For example, the number of pixels 10A that are included in the imaging device 100A may be 1. Although, in this example, the center of each pixel 10A is located at a lattice point of a tetragonal lattice, the pixels 10A may not be arranged in that manner. For example, the plurality of pixels 10A may be placed so that the center of each pixel 10A is located at a lattice point of a triangular lattice, a hexagonal lattice, or other lattices. Further, arraying the pixels 10A one-dimensionally allows the imaging device 100A to be utilized as a line sensor.

In the configuration illustrated in FIG. 1, the peripheral circuit 40 includes a vertical scanning circuit 46 and a horizontal signal readout circuit 48. The vertical scanning circuit 46 is also called a “row scanning circuit” and has connections to address signal lines 34 provided separately in correspondence with each of the rows of pixels 10A. The horizontal signal readout circuit 48 is also called a “column scanning circuit” and has connections to vertical signal lines 35 provided separately in correspondence with each of the columns of pixels 10A. As schematically shown in FIG. 1, these circuits are placed in a peripheral region R2 located outside the imaging region R1. The peripheral circuit 40 is a circuit that is connected to the plurality of pixels 10A to acquire a signal from each pixel 10A, and the peripheral circuit 40 may further include a load circuit, a signal processing circuit, an output circuit, a control circuit, a power supply that supplies a predetermined voltage to each pixel 10A, or other circuits.

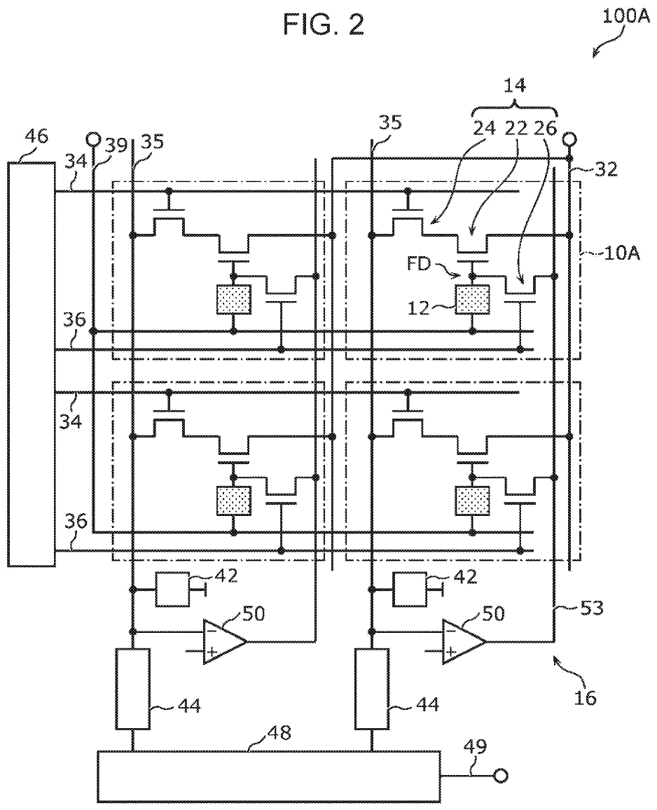

FIG. 2 is a diagram showing a circuit configuration of the imaging device 100A according to the present embodiment. For the avoidance of a complex drawing, FIG. 2 shows, of the plurality of pixels 10A shown in FIG. 1, four pixels 10A arrayed in two rows and two columns.

The photoelectric converter 12 of each pixel 10A generates positive and negative electric charges upon receiving light falling thereon. That is, the photoelectric converter 12 converts light into electric charge. The positive and negative electric charges are typically a hole-electron pair. The photoelectric converter 12 of each pixel 10A has a connection to an accumulation control line 39, and when the imaging device 100A is in operation, a predetermined voltage is applied to the accumulation control line 39. Applying the predetermined voltage to the accumulation control line 39 allows either of the positive and negative electric charges generated by photoelectric conversion to be selectively accumulated as signal charge in a charge accumulation region. Unless otherwise noted, the following description illustrates a case where of the positive and negative electric charges generated by photoelectric conversion, the positive electric charge, i.e. a hole, is utilized as signal charge.

Each pixel 10A includes a signal detection circuit 14 electrically connected to the photoelectric converter 12. In the configuration illustrated in FIG. 2, the signal detection circuit 14 includes an amplifying transistor 22 and a reset transistor 26. The amplifying transistor 22 is also called a “readout transistor”. In the example shown in FIG. 2, the signal detection circuit 14 further includes an address transistor 24. The address transistor 24 is also called a “row selection transistor”. As will be described in detail later with reference to the drawings, the amplifying transistor 22, reset transistor 26, and address transistor 24 of the signal detection circuit 14 are, for example, field-effect transistors (FETs) formed, for example, on the semiconductor substrate 60, which supports the photoelectric converter 12. Further, in the example shown in FIG. 2, N-channel MOSFETs (metal-oxide semiconductor FETs) are used as the amplifying transistor 22, the reset transistor 26, and the address transistor 24. It should be noted that which of the two diffusion regions of an FET corresponds to a source or a drain is determined by the polarity of the FET and whether the potential is high or low at that point in time. Therefore, which is a source or a drain can vary with the operating condition of the FET. That is, a source and drain of each transistor described below can be opposite in configuration, depending on the operating condition of the FET.

As schematically shown in FIG. 2, a gate of the amplifying transistor 22 is electrically connected to the photoelectric converter 12. Electric charge generated by the photoelectric converter 12 is accumulated as signal charge in a charge accumulation node FD between the photoelectric converter 12 and the amplifying transistor 22. That is, the charge accumulation node FD functions as at least part of the charge accumulation region in which to accumulate signal charge, and the potential of the charge accumulation node FD corresponds to the amount of signal charge accumulated in the charge accumulation region. The charge accumulation node FD includes a wire connecting the photoelectric converter 12, the amplifying transistor 22, and the reset transistor 26.

Either a source or drain of the amplifying transistor 22 is connected to a power supply wire 32 that supplies a predetermined power supply voltage VDD to each pixel 10A when the imaging device 100A is in operation. Although the predetermined power supply voltage VDD is, for example, approximately 3.3 V, this is not intended to impose any limitation. The amplifying transistor 22 outputs a signal voltage corresponding to the amount of signal charge generated by the photoelectric converter 12. The other of the source and drain of the amplifying transistor 22 is connected to either a source or drain of the address transistor 24.

To the other of the source and drain of the address transistor 24, a vertical signal line 35 is connected. As shown in FIGS. 1 and 2, such vertical signal lines 35 are provided separately for each of the columns of the plurality of pixels 10A, and to each of the vertical signal lines 35, a load circuit 42 and a column signal processing circuit 44 are connected. The column signal processing circuit 44 is also called a “row signal accumulation circuit”. For example, the load circuit 42 forms a source-follower circuit together with the amplifying transistor 22.

To a gate of the address transistor 24, an address signal line 34 is connected. Such address signal lines 34 are provided separately for each of the rows of the plurality of pixels 10A. The address signal line 34 is connected to the vertical scanning circuit 46, and the vertical scanning circuit 46 applies to the address signal line 34 a row selection signal that controls the turning on and turning off of the address transistor 24. With this, a row to be read out is scanned in a vertical direction (i.e. a column-wise direction), and the row to be read out is selected. By controlling the turning on and turning off of the address transistors 24 via the address signal line 34, the vertical scanning circuit 46 can read out, to the corresponding vertical signal line 35, the output of the amplifying transistors 22 of the pixels 10A thus selected. The placement of the address transistor 24 is not limited to the example shown in FIG. 2 but may be between either the source or drain of the amplifying transistor 22 and the power supply wire 32.

After being outputted to the vertical signal line 35 via the address transistors 24, signal voltages from the pixels 10A are inputted to the corresponding one of a plurality of the column signal processing circuits 44 provided separately for each of the columns of the plurality of pixels 10A in correspondence with the vertical signal lines 35. The column signal processing circuit 44 and the load circuit 42 can be part of the aforementioned peripheral circuit 40.

The column signal processing circuit 44 performs noise suppression signal processing and analog-digital conversion (AD conversion) typified by correlated double sampling. The column signal processing circuit 44 is connected to the horizontal signal readout circuit 48. The horizontal signal readout circuit 48 reads out signals in sequence from the plurality of column signal processing circuits 44 to a horizontal common signal line 49.

In the example shown in FIG. 2, either a source or drain of the reset transistor 26 of the signal detection circuit 14 is connected to the charge accumulation node FD. To a gate of the reset transistor 26, a reset signal line 36 having a connection to the vertical scanning circuit 46 is connected. As is the case with the address signal line 34, such reset signal lines 36 are provided separately for each of the rows of the plurality of pixels 10A. By applying a row selection signal to the address signal line 34, the vertical scanning circuit 46 can select, on a row-by-row basis, pixels 10A to be reset. Further, by applying, via the reset signal line 36 to the gates of the reset transistors 26, reset signals that control the turning on and turning off of the reset transistors 26, the vertical scanning circuit 46 can turn on the reset transistors 26 of the row thus selected. The turning on of the reset transistors 26 causes the potentials of the charge accumulation nodes FD to be reset.

In the example shown in FIG. 2, the other of the source and drain of the reset transistor 26 is connected to one of feedback lines 53 provided separately for each of the columns of the plurality of pixels 10A. That is, in this example, a voltage of the feedback line 53 is supplied to the charge accumulation node FD as a reset voltage that initializes the signal charge generated by the photoelectric converter 12. The aforementioned feedback line 53 is here connected to an output terminal of the corresponding one of inverting amplifiers 50 provided separately for each of the columns of the plurality of pixels 10A. The inverting amplifier 50 can be part of the aforementioned peripheral circuit 40.

Attention is paid here to one of the columns of the plurality of pixels 10A. As shown in FIG. 2, an inverting input terminal of the inverting amplifier 50 is connected to the vertical signal line 35 of the column. Further, the output terminal of the inverting amplifier 50 and one or more pixels 10A belonging to the column are connected to each other via the feedback line 53. When the imaging device 100A is in operation, a predetermined input voltage Vref is supplied to the inverting input terminal of the inverting amplifier 50. By the vertical scanning circuit 46 selecting one of the one or more pixels 10A belonging to the column and turning on the address transistor 24 and the reset transistor 26, a feedback path through which the output of the pixel 10A is negatively fed back can be formed. The formation of the feedback path causes the voltage of the vertical signal line 35 to converge at the input voltage Vref to the inverting input terminal of the inverting amplifier 50. In other words, the formation of the feedback path causes the voltage of the charge accumulation node FD to be reset to such a voltage that the voltage of the vertical signal line 35 becomes equal in magnitude to the input voltage Vref. A usable example of the input voltage Vref is a voltage of arbitrary magnitude falling within a range of power supply voltage and ground voltage. For example, the input voltage Vref is a voltage falling within a range of 0 V to 3.3 V. As one example, the input voltage Vref is a positive voltage of 1 V or approximately 1 V. The inverting amplifier 50 is also called a “feedback amplifier”. Thus, the imaging device 100A has a feedback circuit 16 including the inverting amplifier 50 as part of the feedback path.

As is well known, thermal noise called kTC noise is generated along with the turning on or turning off of a transistor. Noise that is generated along with the turning on or turning off of a reset transistor 26 is called reset noise. After the potential of the charge accumulation region has been reset, reset noise generated by turning off the reset transistor 26 remains in the charge accumulation region before signal charge is accumulated in the charge accumulation region. However, reset noise generated by turning off the reset transistor 26 can be reduced through the use of feedback. Suppression of reset noise through the use of feedback is described in detail in International Publication No. 2012/147302, the entire contents of which are hereby incorporated by reference.

In the configuration illustrated in FIG. 2, the formation of the feedback path causes an alternating-current component of thermal noise to be fed back to the other of the source and drain of the reset transistor 26. In the configuration illustrated in FIG. 2, the feedback path is formed until just before the turning off of the reset transistor 26, so that reset noise that is generated along with the turning off of the reset transistor 26 can be reduced.

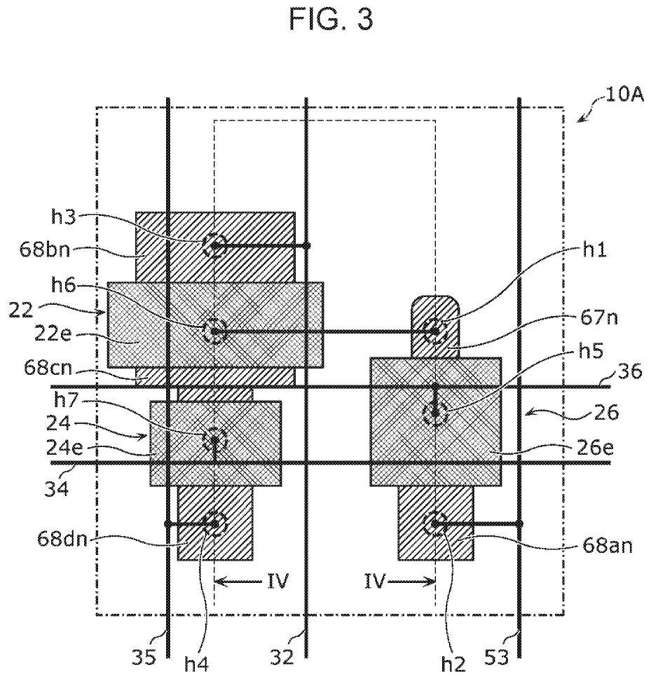

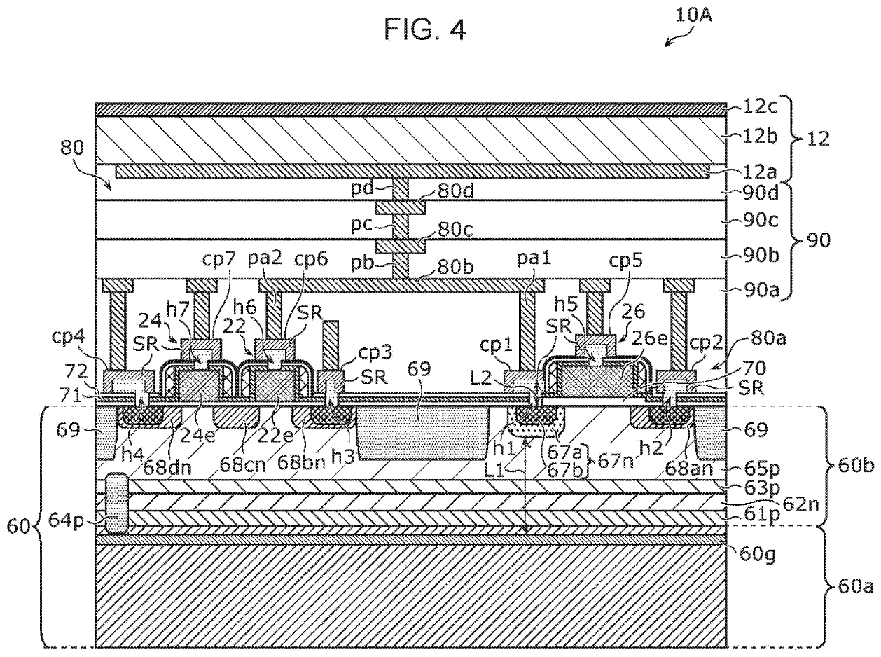

FIG. 3 is a plan view showing a layout of the inside of a pixel 10A according to the present embodiment. FIG. 4 is a schematic cross-sectional view of a device structure of the pixel 10A according to the present embodiment. FIG. 4 is a cross-sectional view of the pixel 10A as taken along line IV-IV in FIG. 3 in the directions of arrows. FIG. 3 schematically shows the placement of each device formed on the semiconductor substrate 60, with the pixel 10A shown in FIG. 4 seen from a direction perpendicular to the semiconductor substrate 60. Specifically, FIG. 3 shows the placement of the amplifying transistor 22, address transistor 24, and reset transistor 26 of the pixel 10A. In this example, the amplifying transistor 22 and the address transistor 24 are arranged in a linear fashion along an up-down direction on the page. Further, FIG. 3 schematically shows electrical connections between devices formed on the semiconductor substrate 60. In FIG. 3, for viewability, each component shown in a plan view is hatched in the same manner as each component shown in the cross-section of FIG. 4 is hatched. Further, for viewability, FIG. 4 omits hatching that indicates cross-sections of insulating layers 70 and 72 and an interlayer insulating layer 90.

As schematically shown in FIG. 4, the pixel 10A schematically includes the semiconductor substrate 60, a photoelectric converter 12 placed above the semiconductor substrate 60, and a wiring structure 80. Each pixel 10A has, for example, substantially the same device structure. The wiring structure 80 is placed within the interlayer insulating layer 90 formed between the photoelectric converter 12 and the semiconductor substrate 60 and includes a structure that electrically connects the amplifying transistor 22 formed on the semiconductor substrate 60 to the photoelectric converter 12. In this example, the interlayer insulating layer 90 has a stack structure including four insulating layers, namely insulating layers 90a, 90b, 90c, and 90d, and the wiring structure 80 includes four wiring layers, namely wiring layers 80a, 80b, 80c, and 80d, and plugs pa1, pa2, pb, pc, and pd placed between these wiring layers. It should be noted that the number of insulating layers in the interlayer insulating layer 90 and the number of wiring layers in the wiring structure 80 are not limited to this example but can be arbitrarily set. The semiconductor substrate 60 and the interlayer insulating layer 90 are continuously formed, for example, at least all over the imaging region R1 and are shared by the plurality of pixels 10A. Further, the semiconductor substrate 60 and the interlayer insulating layer 90 may be continuously formed astride the imaging region R1 and the peripheral region R2.

The photoelectric converter 12 is placed on top of the interlayer insulating layer 90. The photoelectric converter 12 includes a pixel electrode 12a formed on top of the interlayer insulating layer 90, a transparent electrode 12c facing the pixel electrode 12a, and a photoelectric conversion layer 12b located between the pixel electrode 12a and the transparent electrode 12c. The photoelectric conversion layer 12b of the photoelectric converter 12 is formed from an organic material or an inorganic material such as amorphous silicon and, upon receiving light falling thereon via the transparent electrode 12c, generates positive and negative electric charges by photoelectric conversion. The photoelectric conversion layer 12b is, for example, continuously formed across the plurality of pixels 10A. That is, the photoelectric conversion layer 12b is shared by the plurality of pixels 10A. Further, the photoelectric conversion layer 12b may include a layer composed of an organic material and a layer composed of an inorganic material. Further, the photoelectric conversion layer 12b may be divided into parts provided separately for each of the pixels 10A.

The transparent electrode 12c is formed from a transparent conductive material such as ITO (indium tin oxide) and placed on a light-receiving surface of the photoelectric conversion layer 12b. The term “transparent” herein means to transmit at least part of light of wavelengths that the photoelectric conversion layer 12b can absorb, and it is not essential to transmit light across the whole wavelength range of visible light. For example, as is the case with the photoelectric conversion layer 12b, the transparent electrode 12c is continuously formed across the plurality of pixels 10A. That is, the transparent electrode 12c is shared by the plurality of pixels 10A. In other words, the photoelectric converters 12 provided separately for each of the pixels 10A include parts of the transparent electrode 12c that are different from one pixel 10A to another. The transparent electrode 12c may be divided into parts provided separately for each of the pixels 10A

Although not illustrated in FIG. 4, the transparent electrode 12c has a connection to the aforementioned accumulation control line 39. When the imaging device 100A is in operation, signal charge generated by photoelectric conversion can be collected by the pixel electrode 12a by making the potential of the transparent electrode 12c and the potential of the pixel electrode 12a different from each other by controlling the potential of the accumulation control line 39. For example, the potential of the accumulation control line 39 is controlled so that the potential of the transparent electrode 12c becomes higher than the potential of the pixel electrode 12a. Specifically, a positive voltage of, for example, approximately 10 V is applied to the accumulation control line 39. With this, a hole of a hole-electron pair generated by the photoelectric conversion layer 12b can be collected as signal charge by the pixel electrode 12a. The signal charge collected by the pixel electrode 12a is accumulated in the after-mentioned n-type impurity region 67n electrically connected to the pixel electrode 12a via the wiring structure 80. In a case where an electron is used as signal charge, such a voltage is applied to the transparent electrode 12c that the potential of the transparent electrode 12c becomes lower than the potential of the pixel electrode 12a.

The pixel electrode 12a is an electrode formed from a metal such as aluminum or copper, from a metal nitride, from polysilicon rendered conductive by being doped with impurities, or from other substances. The pixel electrode 12a is electrically separated from the pixel electrodes 12a of other adjacent pixels 10A by being spatially separated from the pixel electrodes 12a of the other pixels 10A.

The semiconductor substrate 60 includes a base substrate 60a and an epitaxial layer 60b including one or more semiconductor layers formed on top of the base substrate 60a. In this example, a p-type silicon (Si) substrate doped with p-type impurities such as boron (B) is illustrated as the base substrate 60a.

Further, in the example shown in FIG. 4, the epitaxial layer 60b includes a p-type semiconductor layer 61p on top of the base substrate 60a, an n-type semiconductor layer 62n on top of the p-type semiconductor layer 61p, a p-type semiconductor layer 63p on top of the n-type semiconductor layer 62n, and a p-type semiconductor layer 65p on top of the p-type semiconductor layer 63p. The p-type semiconductor layer 65p is a semiconductor layer that is located uppermost, i.e. closest to the photoelectric converter 12, of the semiconductor layers included in the semiconductor substrate 60. The p-type semiconductor layer 61p, the p-type semiconductor layer 63p, and the p-type semiconductor layer 65p are semiconductor layers containing p-type impurities. The configuration of one or more semiconductor layers included in the epitaxial layer 60b is not limited to particular configurations but can be designed for any purpose.

The semiconductor substrate 60 further includes a gettering layer 60g located within the base substrate 60a. The gettering layer 60g is an example of a third impurity region. The gettering layer 60g faces a silicide region SR across the after-mentioned n-type impurity regions 67n, 68an, 68bn, and 68dn. The gettering layer 60g overlaps the n-type impurity regions 67n, 68an, 68bn, and 68dn in a plan view. Although, in the example shown in FIG. 4, the gettering layer 60g is provided a short distance away from an upper surface of the base substrate 60a, the gettering layer 60g may be provided in a portion including the upper surface of the base substrate 60a. The gettering layer 60g is continuously formed, for example, at least all over the imaging region R1 and is shared by the plurality of pixels 10A. The gettering layer 60g may be divided into parts formed separately for each of the pixels 10A or for each pixel block constituted by two or more pixels 10A. Further, as long as the gettering layer 60g is provided opposite the silicide region SR, there may be a place where the gettering layer 60g is not provided within the pixel 10A in a plan view.

The gettering layer 60g contains a group 14 element other than silicon as an impurity element and is formed by ion implantation of the impurity element into the base substrate 60a. The gettering layer 60g getters a metallic impurity in the semiconductor substrate 60 with the group 14 element other than silicon. This makes it possible to reduce a leak current at a p-n junction within the semiconductor substrate 60. For example, a dark current flowing through the n-type impurity region 67n in which signal charge is accumulated is reduced. The gettering layer 60g is formed, for example, prior to the formation of the epitaxial layer 60b. Further, the crystallinity of the base substrate 60a may be increased by performing heat treatment prior to the formation of the epitaxial layer 60b after the gettering layer 60g has been formed on the base substrate 60.

The group 14 element other than silicon is, for example, carbon. The group 14 element other than silicon may be germanium. In a case where the group 14 element other than silicon is carbon, the gettering layer 60g may be formed by irradiating the base substrate 60a with carbon-containing cluster ions. In this case, the gettering layer 60g further contains hydrogen derived from the carbon-containing cluster ions. Further, the gettering layer 60g may further contain oxygen. In the gettering layer 60g, oxygen in the semiconductor substrate 60 can gather during ion implantation of the group 14 element other than silicon into the base substrate 60a. Oxygen in the gettering layer 60g getters the metallic impurity in the semiconductor substrate 60.

The concentration of the group 14 element other than silicon in the gettering layer 60g is, for example, higher than or equal to 1×10¹⁶ atoms/cm³. The concentration of the group 14 element other than silicon in the gettering layer 60g may be higher than or equal to 1×10¹⁷ atoms/cm³ or may be higher than or equal to 1×10¹⁸ atoms/cm³. Further, the concentration of the group 14 element other than silicon in the gettering layer 60g may be lower than or equal to 1×10²¹ atoms/cm³.

Further, in a case where the gettering layer 60g contains oxygen, the concentration of oxygen in the gettering layer 60g may be higher than or equal to 1×10¹⁶ atoms/cm³ or may be higher than or equal to 1×10¹⁸ atoms/cm³. Further, the concentration of oxygen in the gettering layer 60g may be lower than or equal to 1×10²⁰ atoms/cm³.

The concentration of an element in the gettering layer 60g is herein a peak concentration in a position corresponding to the gettering layer 60g in a case where an element concentration distribution is measured in a depth direction (i.e. a thickness direction of the semiconductor substrate 60).

The semiconductor substrate 60 further includes n-type impurity regions 67n, 68an, 68bn, 68cn, and 68dn and a device isolation region 69. The n-type impurity regions 67n, 68an, 68bn, 68cn, and 68dn and the device isolation region 69 are located within the p-type semiconductor layer 65p and partially located at an upper surface of the p-type semiconductor layer 65p. The n-type impurity regions 67n, 68an, 68bn, 68cn, and 68dn are each an impurity diffusion region in which an n-type impurity is diffused. The n-type impurity regions 67n, 68an, 68bn, 68cn, and 68dn are provided in different positions in the semiconductor substrate 60 in a plan view. In the present embodiment, the n-type impurity region 67n is an example of a first impurity region, and one of the n-type impurity regions 68an, 68bn, and 68dn is an example of a second impurity region.

As shown in FIGS. 3 and 4, the amplifying transistor 22, the address transistor 24, and the reset transistor 26 are formed on the semiconductor substrate 60.

In FIGS. 3 and 4, the n-type impurity region 67n is either the source or drain of the reset transistor 26. Further, the n-type impurity region 67n is a charge accumulation region that is electrically connected to the photoelectric converter 12 and in which signal charge generated by the photoelectric converter 12 is temporarily accumulated. The reset transistor 26 initializes the electric charge of the n-type impurity region 67n by being turned on.

The reset transistor 26 includes the n-type impurity regions 67n and 68an, the insulating layer 70 formed on top of the semiconductor substrate 60, and a gate electrode 26e on top of the insulating layer 70. The reset transistor 26 includes the n-type impurity region 67n, in which light charge converted by the photoelectric converter 12 is accumulated, as one of the source and the drain and includes the n-type impurity region 68an as the other of the source and the drain. Further, the reset transistor 26 includes the gate electrode 26e on top of the insulating layer 70 as the gate.

The concentration of the n-type impurity in the n-type impurity region 67n is, for example, lower than the concentration of the n-type impurity in the n-type impurity region 68an.

The amplifying transistor 22 includes the n-type impurity regions 68bn and 68cn, part of the insulating layer 70, and a gate electrode 22e on top of the insulating layer 70. The amplifying transistor 22 includes the n-type impurity region 68bn as one of the source and the drain and includes the n-type impurity region 68cn as the other of the source and the drain. Further, the amplifying transistor 22 includes the gate electrode 22e on top of the insulating layer 70 as the gate.

The address transistor 24 includes the n-type impurity regions 68cn and 68dn, part of the insulating layer 70, and a gate electrode 24e on top of the insulating layer 70. In the example shown in FIGS. 3 and 4, the address transistor 24 is electrically connected to the amplifying transistor 22 by sharing the n-type impurity region 68cn with the amplifying transistor 22. The address transistor 24 includes the n-type impurity region 68cn as one of the source and the drain and includes the n-type impurity region 68dn as the other of the source and the drain. Further, the address transistor 24 includes the gate electrode 24e on top of the insulating layer 70 as the gate.

The concentration of the n-type impurity in the n-type impurity region 67n may be lower than the concentrations of the n-type impurities in the n-type impurity regions 68bn, 68dn, and 68cn. This brings about a reduction in junction concentration at a junction between the n-type impurity region 67n and the p-type semiconductor layer region 65p, thus making it possible to lessen electric field strength at the junction. This reduces a leak current from the n-type impurity region 67n, which is a charge accumulation region, or to the n-type impurity region 67n.

Further, the concentrations of the n-type impurity contained in the n-type impurity region 67n and the p-type impurity contained in the p-type semiconductor layer region 65p may be higher than or equal to 1×10¹⁶ atoms/cm³ and lower than or equal to 5×10¹⁶ atoms/cm³. This brings about a reduction in junction concentration between the n-type impurity region 67n and the p-type semiconductor layer 65p, making it possible to suppress the rise in electric field strength at the junction. This makes it possible to reduce a leak current at the junction.

The p-type semiconductor layer 61p, the n-type semiconductor layer 62n, the p-type semiconductor layer 63p, and the p-type semiconductor layer 65p are each formed, for example, by ion implantation of an impurity into a semiconductor layer formed by epitaxial growth. The concentrations of the impurities in the p-type semiconductor layer 63p and the p-type semiconductor layer 65p are, for example, about equal to each other and higher than the concentration of the impurity in the p-type semiconductor layer 61p. The n-type semiconductor layer 62n, which is placed between the p-type semiconductor layer 61p and the p-type semiconductor layer 63p, inhibits the inflow of minority carriers from the base substrate 60a or the peripheral circuit 40 into the n-type impurity region 67n, which is a charge accumulation region in which signal charge is accumulated. When the imaging device 100A is in operation, the potential of the n-type semiconductor layer 62n is controlled via a contact (not illustrated) provided outside the imaging region R1 shown in FIG. 1.

Further, in this example, the semiconductor substrate 60 includes a p-type region 64p provided between the p-type semiconductor layer 65p and the base substrate 60a in such a manner as to penetrate through the p-type semiconductor layer 61p, the n-type semiconductor layer 62n, and the p-type semiconductor layer 63p. The p-type region 64p may not penetrate through the p-type semiconductor layer 63p to reach the p-type semiconductor 65p, as long as the p-type region 64p reaches the p-type semiconductor layer 63p. The p-type region 64p has a higher impurity concentration than do the p-type semiconductor layers 63p and 65p and electrically connects the p-type semiconductor layers 63p and 65p to the base substrate 60a. Further, although, in the example shown in FIG. 4, the p-type region 64p is in contact with an upper surface of the gettering layer 60g, the p-type region 64p may penetrate through the gettering layer 60g or may not be in contact with the gettering layer 60g.

When the imaging device 100A is in operation, the potentials of the p-type semiconductor layers 63p and 65p and the base substrate 60a are controlled via the contact (not illustrated) provided outside the imaging region R1. Further, placing the p-type semiconductor layer 65p in contact with the p-type semiconductor layer 63p makes it also possible to control the potential of the p-type semiconductor layer 65p via the p-type semiconductor layer 63p when the imaging device 100A is in operation. The p-type semiconductor layer 65p may be provided with a contact opposite to the base substrate 60a so that the potential may be controlled via the contact.

The concentration of the p-type impurity contained in the base substrate 60a may be, for example, higher than the concentrations of the p-type impurities contained in the p-type semiconductor layers 61p, 63p, and 65p. Specifically, the concentration of the p-type impurity contained in the base substrate 60a is, for example, higher than or equal to 1×10¹⁸ atoms/cm³ and lower than or equal to 1×10¹⁹ atoms/cm³. This makes it possible to bring about an effect of gettering the metallic impurity in the semiconductor substrate 60 with a comparatively high concentration of a p-type impurity, making it possible to reduce a leak current at the p-n junction in the semiconductor substrate 60. For example, a dark current flowing through the n-type impurity region 67n, in which signal charge is accumulated, can be reduced. Further, since the resistance of the base substrate 60a decreases, the potential of a well in the semiconductor substrate 60 can be stabilized. The concentration of the p-type impurity contained in the base substrate 60a may be higher than or equal to 2×10¹⁸ atoms/cm³ and lower than or equal to 6×10¹⁸ atoms/cm³.

The device isolation region 69 is placed between the n-type impurity region 68bn and the n-type impurity region 67n. The device isolation region 69 is, for example, a p-type impurity diffusion region. The device isolation region 69 causes the amplifying transistor 22 and the reset transistor 26 to be electrically separated from each other.

As schematically shown in FIG. 4, the n-type impurity region 67n and the device isolation region 69 may be placed out of contact with each other. For example, in a case where a p-type impurity layer is used as the device isolation region 69, contact between the n-type impurity region 67n and the device isolation region 69 makes both an n-type impurity concentration and a p-type impurity concentration at the junction higher. Therefore, a leak current attributed to this high junction concentration tends to be generated in an area around the junction between the n-type impurity region 67n and the device isolation region 69. In other words, placing the n-type impurity region 67n and the device isolation region 69 out of contact with each other makes it possible to, even when a high-concentration p-type impurity layer is used as the device isolation region 69, suppress the rise in p-n junction concentration and reduce a leak current. Further, there is a method in which STI (shallow trench isolation) is used as the device isolation region 69. In this case, the n-type impurity region 67n and the STI may be placed out of contact with each other so that a leak current attributed to crystal defects in a STI side wall portion is reduced.

The device isolation region 69 is also placed between pixels 10A that are adjacent to each other and electrically separates the signal detection circuits 14 of these pixels 10A from each other. Note here that the device isolation region 69 is provided around a pair of the amplifying transistor 22 and the address transistor 24 and around the reset transistor 26.

In the example shown in FIG. 4, the pixel 10A is provided with the insulating layer 72 covering the gate electrode 26e of the reset transistor 26, the gate electrode 22e of the amplifying transistor 22, and the gate electrode 24e of the address transistor 24. The insulating layer 72 is, for example, a silicon oxide film. In this example, an insulating layer 71 is further sandwiched between the insulating layer 72 and each of the gate electrodes 26e, 22e, and 24e. The insulating layer 71 is, for example, a silicon oxide film. The insulating layer 71 may have a stack structure including a plurality of insulating layers. Similarly, the aforementioned insulating layer 72 may have a stack structure including a plurality of insulating layers.

The stack structures of the insulating layer 72 and the insulating layer 71 include a plurality of contact holes. In this example, the insulating layer 72 and the insulating layer 71 are provided with contact holes h1, h2, h3, h4, h5, h6, and h7. The pixel 10A further includes contact plugs cp1, cp2, cp3, cp4, cp5, cp6, and cp7 parts of which are placed within the contact holes h1, h2, h3, h4, h5, h6, and h7. The contact plug cp1 is an example of a first plug.

The contact holes h1, h2, h3, and h4 are formed in such positions as to overlap the n-type impurity region 67n, the n-type impurity region 68an, the n-type impurity region 68bn, and the n-type impurity region 68dn, respectively, in a plan view of the semiconductor substrate 60. The contact holes h1, h2, h3, and h4 are bored through the insulating layer 72, the insulating layer 71, and the insulating layer 70. In the positions of the contact holes h1, h2, h3, and h4, the contact plugs cp1, cp2, cp3, and cp4 are placed, respectively. The contact plugs cp1, cp2, cp3, and cp4 are connected to the n-type impurity region 67n, the n-type impurity region 68an, the n-type impurity region 68bn, and the n-type impurity region 68dn, respectively.

The contact holes h5, h6, and h7 are formed in such positions as to overlap the gate electrode 26e, the gate electrode 22e, and the gate electrode 24e, respectively, in a plan view of the semiconductor substrate 60. The contact holes h5, h6, and h7 are bored through the insulating layer 72 and the insulating layer 71. In the positions of the contact holes h5, h6, and h7, the contact plugs cp5, cp6, and cp7 are placed, respectively. The contact plugs cp5, cp6, and cp7 are connected to the gate electrode 26e, the gate electrode 22e, and the gate electrode 24e, respectively.

The wiring layer 80a is placed in the insulating layer 90a. In the configuration illustrated in FIG. 4, the wiring layer 80a is a layer including the contact plugs cp1, cp2, cp3, cp4, cp5, cp6, and cp7 and the gate electrodes 22e, 24e, and 26e and is, for example, a polysilicon layer doped with impurities such as n-type impurities. That is, for example, the contact plugs cp1, cp2, cp3, cp4, cp5, cp6, and cp7 and the gate electrodes 22e, 24e, and 26e contain, as a constituent material, polysilicon rendered conductive by being doped with impurities. This makes it possible to reduce the diffusion of metal into the semiconductor substrate 60 from contact plugs connected to the amplifying transistor 22, the address transistor 24, and the reset transistor 26. A prime constituent element of the contact plugs cp1, cp2, cp3, cp4, cp5, cp6, and cp7 and the gate electrodes 22e, 24e, and 26e is, for example, silicon. The term “prime constituent element” here means that the content is higher than 50 atom %.

The wiring layer 80a is placed closest to the semiconductor substrate 60 of the wiring layers including the wiring structure 80. The wiring layer 80b and the plugs pa1 and pa2 are placed within the insulating layer 90a. The plug pa1 connects the contact plug cp1 to the wiring layer 80b, and the plug pa2 connects the contact plug cp6 to the wiring layer 80b. That is, the n-type impurity region 67n and the gate electrode 22e of the amplifying transistor 22 are electrically connected to each other via the contact plugs cp1 and cp6, the plugs pa1 and pa2, and the wiring layer 80b.

The contact plugs cp1, cp2, cp3, cp4, cp5, cp6, and cp7 each include the silicide region SR. The silicide region SR is, for example, a silicide layer containing metallic silicide formed by depositing a metal on surfaces of the contact plugs cp1, cp2, cp3, cp4, cp5, cp6, and cp7 and then causing the metal and polysilicon to react with each other. The silicide region SR is formed on at least upper surfaces of the contact plugs cp1, cp2, cp3, cp4, cp5, cp6, and cp7. In the example shown in FIG. 4, the silicide region SR is also formed on side surfaces of the contact plugs cp1, cp2, cp3, cp4, cp5, cp6, and cp7. The silicide region SR is not formed on surfaces of the contact plugs cp1, cp2, cp3, cp4, cp5, cp6, and cp7 that face the semiconductor substrate 60. Further, no silicide region is formed in the n-type impurity regions 67n, 68an, 68bn, 68cn, and 68dn, and for example, in the pixel 10A, no silicide region is present within the semiconductor substrate 60.

In the silicide region SR, the contact plugs cp1, cp2, cp3, cp4, cp5, cp6, and cp7 each make contact with a plug included in the wiring structure 80. This brings about a reduction in contact resistance between each of the contact plugs cp1, cp2, cp3, cp4, cp5, cp6, and cp7 and the plug. The contact plugs cp1, cp2, cp3, cp4, cp5, cp6, and cp7 are connecting portions between the amplifying transistor 22 and the wiring structure 80, between the address transistor 24 and the wiring structure 80, and between the reset transistor 26 and the wiring structure 80, and making the connecting portions lower in resistance can improve the driving capabilities of these transistors.

Examples of metals that are used to form the silicide region SR include nickel, platinum, titanium, tungsten, and cobalt. One type of metal may be used to form the silicide region SR, or two or more types of metal may be used to form the silicide region SR. From the point of view of reducing contact resistance with the plug, the metallic silicide of the silicide region SR may contain nickel.

The wiring layer 80b is placed within the insulating layer 90a and can include the aforementioned lines and wires such as the vertical signal line 35, the address signal line 34, the power supply wire 32, the reset signal lines 36, and the feedback line 53 as part thereof. The vertical signal line 35, the address signal line 34, the power supply wire 32, the reset signal lines 36, and the feedback line 53 are electrically connected to the n-type impurity region 68dn, the gate electrode 24e, the n-type impurity region 68bn, the gate electrode 26e, and the n-type impurity region 68an via the contact plugs cp4, cp7, cp3, cp5, and cp2, respectively.

At least one of the vertical signal line 35, the address signal line 34, the power supply wire 32, the reset signal lines 36, and the feedback line 53 may be included not in the wiring layer 80b but in the wiring layer 80c or 80d.

The plug pb placed within the insulating layer 90b connects the wiring layer 80b to the wiring layer 80c. Similarly, the plug pc placed within the insulating layer 90c connects the wiring layer 80c to the wiring layer 80d. The plug pd placed within the insulating layer 90d connects the wiring layer 80d to the pixel electrode 12a of the photoelectric converter 12. The wiring layers 80b, 80c, and 80d and the plugs pa1, pa2, pb, pc, and pd are formed, for example, from a metal such as copper or tungsten, a metallic compound such as a metallic nitride or a metallic oxide, or other substances. Further, the plugs other than the plugs pa1 and pa2 (including those connected to the contact plugs cp2, cp3, cp4, cp5, and cp7) are formed, for example, from a metal such as copper or tungsten, a metallic compound such as a metallic nitride or a metallic oxide, or other substances.

The plugs pa1, pa2, pb, pc, and pd, the wiring layers 80b, 80c, and 80d, and the contact plugs cp1 and cp6 electrically connect the photoelectric converter 12 to the signal detection circuit 14 formed on the semiconductor substrate 60. The plugs pa1, pa2, pb, pc, and pd, at least part of the wiring layers 80b, 80c, and 80d, the contact plugs cp1 and cp6, the pixel electrode 12a of the photoelectric converter 12, the gate electrode 22e of the amplifying transistor 22, and the n-type impurity region 67n function as a charge accumulation region in which to accumulate signal charge generated by the photoelectric converter 12.

Attention is paid here to the n-type impurity regions formed in the semiconductor substrate 60. Of the n-type impurity regions formed in the semiconductor substrate 60, the n-type impurity region 67n is placed within the p-type semiconductor layer 65p as a p well. The n-type impurity region 67n is formed near a surface of the semiconductor substrate 60, and at least part of the n-type impurity region 67n is located on the surface of the semiconductor substrate 60. A junction capacitor formed by a p-n junction between the p-type semiconductor layer 65p and the n-type impurity region 67n functions as a capacitor that accumulates at least part of the signal charge, and constitutes part of the charge accumulation region.

In the configuration illustrated in FIG. 4, the n-type impurity region 67n includes a first region 67a and a second region 67b. The first region 67a of the n-type impurity region 67n is, for example, lower in impurity concentration than the n-type impurity region 68an and the n-type impurity regions 68bn, 68cn, and 68dn. The second region 67b of the n-type impurity region 67n is formed within the first region 67a and has a higher impurity concentration than does the first region 67a. Further, the contact hole h1 is located on top of the second region 67b, and the contact plug cp1 is connected to the second region 67b via the contact hole h1. The n-type impurity region 67n may not include the first region 67a and the second region 67b and may be constituted by one region formed by combining the first region 67a and the second region 67b with no difference in impurity concentration therebetween. Further, although, in the example shown in FIG. 4, the n-type impurity region 68an and the n-type impurity regions 68bn and 68dn each include two regions differing in impurity concentration from each other, each of them may be constituted by a single region.

Such a device structure of a pixel 10A in the imaging device 100A as that described above can be manufactured, for example, through the use of a common semiconductor manufacturing process.

As noted above, an imaging device 100A according to the present embodiment includes a photoelectric converter 12, a semiconductor substrate 60 including an n-type impurity region 67n serving as a charge accumulation region that is electrically connected to the photoelectric converter 12, and a contact plug cp1 that is connected to the n-type impurity region 67n and that includes a silicide region SR. The semiconductor substrate 60 includes a gettering layer 60g in a position that faces the silicide region SR of the contact plug cp1 across the n-type impurity region 67n.

With this, while the inclusion of the silicide region SR by the contact plug cp1 makes it likely that a metal that is used in the formation of the silicide region SR diffuses as a metallic impurity throughout the semiconductor substrate 60, the metallic impurity is gettered by the gettering layer 60g. This makes it possible to reduce the generation of a leak current due to the diffusion of the metallic impurity from the silicide region SR.

### Concentration of Element in Pixel

Next, the concentration of an element in a pixel 10A is described.

The inventor found out that when the concentration of an element in a pixel 10A satisfies a predetermined condition, a dark current flowing through the n-type impurity region 67n can be effectively reduced. The following describes this point with reference to the results of the analysis conducted by the inventor.

First, the gettering of the metallic impurity by the gettering layer 60g is described.

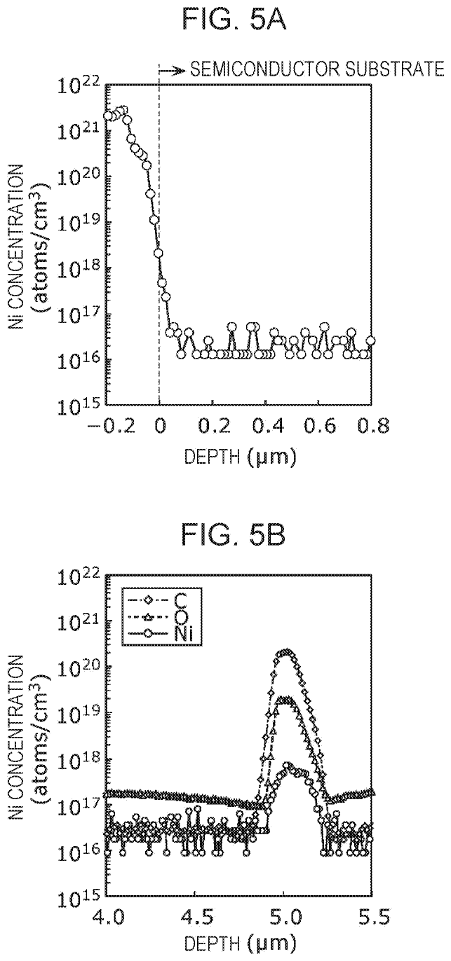

FIG. 5A is a diagram showing a distribution of concentration of nickel (Ni) in the contact plug cp1 and the n-type impurity region 67n. In FIG. 5A, the vertical axis represents the concentration of nickel as expressed by a logarithmic axis, and the horizontal axis represents depth based on the upper surface of the semiconductor substrate 60. The depth direction here is the thickness direction of the semiconductor substrate 60. Further, in FIG. 5A, a minus side of the depth faces the contact plug cp1, and a plus side of the depth faces the n-type impurity region 67n. FIG. 5B is a diagram showing a distribution of impurity concentration in an area near the gettering layer 60g in the semiconductor substrate 60. In FIG. 5B, the vertical axis represents an impurity concentration expressed by a logarithmic axis, and the horizontal axis represents depth based on the upper surface of the semiconductor substrate 60. FIG. 5B shows the concentrations of carbon (C), oxygen (O), and nickel (Ni) as impurities. Further, FIGS. 5A and 5B show results obtained by conducting an elemental analysis of the contact plug cp1 and the semiconductor substrate 60 along the depth direction by an SIMS (secondary ion mass spectrometry) analysis. Further, FIGS. 5A and 5B show the results of a SIMS analysis conducted in a case where nickel was used as a metal for forming the silicide region SR and carbon was used as an impurity element for forming the gettering layer 60g. In FIGS. 5A and 5B, the results in which the element concentration is lower than or equal to 1×10¹⁶ atoms/cm³ are shown as 1×10¹⁶ atoms/cm³, as the results are lower than or equal to a lower detection limit of the SIMS analyzer used.

As shown in FIG. 5A, at a depth corresponding to the position of the contact plug cp1, the nickel concentration is high due to the silicide region SR, as the contact plug cp1 includes the silicide region SR. Further, as shown in FIG. 5B, at a position near the depth of 5.0 μm, where there are peak concentrations of carbon and oxygen derived from the gettering layer 60g, the concentration of nickel is higher than it is at other positions. That is, it is found that nickel is gettered by the gettering layer 60g. Therefore, as shown in FIG. 5A, the gettering of nickel by the gettering layer 60g causes the concentration of nickel to be low at a depth corresponding to the position of the n-type impurity region 67n, and this depth is near the lower detection limit of the analysis. Thus, even in a case where the contact plug cp1 includes the silicide region SR for improvement in driving capability, the metallic impurity in the semiconductor substrate 60 derived from the formation of the silicide region SR is gettered by the gettering layer 60g. This makes it possible to reduce the generation of a leak current within the semiconductor substrate 60.

Next, a relationship between the concentrations of elements in the pixel 10A and a dark current flowing through the n-type impurity region 67n is described.

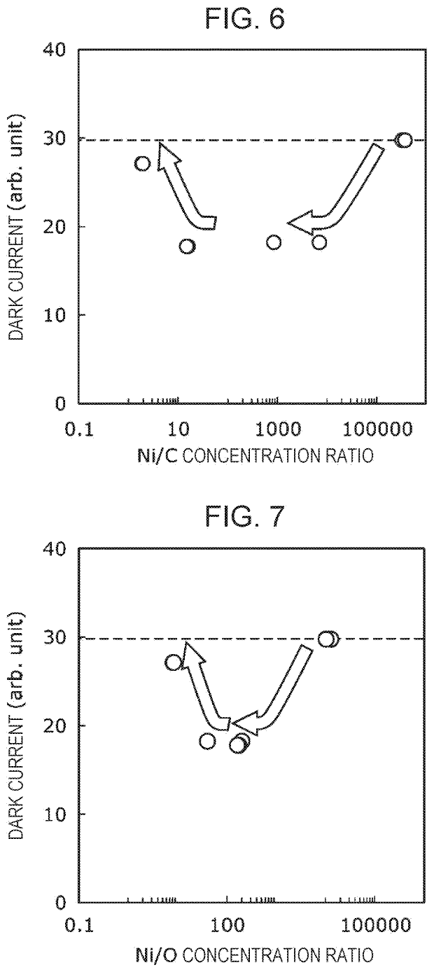

FIG. 6 is a diagram showing a relationship between a ratio of concentration (Ni concentration/C concentration) of nickel (Ni) and carbon (C) and a dark current. In FIG. 6, the vertical axis represents a dark current flowing through the n-type impurity region 67n, and the horizontal axis represents a ratio of concentration (Ni concentration/C concentration) of nickel and carbon as expressed by a logarithmic axis. FIG. 7 is a diagram showing a relationship between a ratio of concentration (Ni concentration/O concentration) of nickel (Ni) and oxygen (O) and a dark current. In FIG. 7, the vertical axis represents a dark current flowing through the n-type impurity region 67n, and the horizontal axis represents a ratio of concentration (Ni concentration/O concentration) of nickel and oxygen as expressed by a logarithmic axis. FIGS. 6 and 7 show results obtained by measuring how a dark current varies in a case where nickel is used as a metal for forming the silicide region SR, where carbon is used as an impurity element for forming the gettering layer 60g, and where the amount of ion implantation of carbon in the formation of the gettering layer 60g is varied. The concentration of nickel (Ni concentration) in this case is a peak value of the concentration of nickel in a position equivalent to the contact plug cp1 as measured by the SIMS analysis. Further, the concentration of carbon (C concentration) is a peak value of the concentration of carbon in a position equivalent to the gettering layer 60g as measured by the SIMS analysis. Further, the concentration of oxygen (O concentration) is a peak value of the concentration of oxygen in a position equivalent to the gettering layer 60g as measured by the SIMS analysis. Further, the rightmost plots in FIGS. 6 and 7 represent results obtained in a case where the gettering layer 60g was not formed.

As shown in FIG. 6, in a case where the gettering layer 60g is formed, the C concentration becomes higher and (Ni concentration)/(C concentration) becomes lower than they are in a case where the gettering layer 60g is not formed, whereby the dark current decreases. A possible reason for this is that the increase in C concentration with respect to the Ni concentration enhances the capability of the gettering layer 60g to getter nickel and suppresses the diffusion of nickel into the n-type impurity region 67n. Meanwhile, a predetermined or more decrease in (Ni concentration)/(C concentration) causes the dark current to shift to an increase. A possible reason for this is that an excessive increase in C concentration with respect to Ni concentration removes more carbon from participation in the gettering of nickel and makes it likely that carbon diffuses from the gettering layer 60g into the n-type impurity region 67n. As shown in FIG. 7, the same can be said of the relationship between (Ni concentration)/(O concentration) and dark current as the relationship between (Ni concentration)/(C concentration) and dark current. That is, while the decrease in (Ni concentration)/(O concentration) causes the dark current to decrease, a predetermined or more decrease in (Ni concentration)/(O concentration) causes the dark current to shift to an increase. A possible reason for this is that an excessive increase in O concentration with respect to Ni concentration removes more oxygen from participation in the gettering of nickel and makes it likely that oxygen diffuses from the gettering layer 60g into the n-type impurity region 67n. Although, in FIGS. 6 and 7, there is no predetermined or more decrease in dark current, this is considered to be a dark current generated by the semiconductor substrate 60 being contaminated by other factors that are not attributed to the silicide region SR or the gettering layer 60g.

Thus, it is found that the impurity element in the gettering layer 60g introduced for a reduction in dark current can act to suppress a reduction in dark current. Therefore, a leak current in the semiconductor substrate 60 can be effectively reduced by controlling, according to the concentration of a metallic element of metallic silicide in the silicide region SR, the concentration of the impurity element of the gettering layer 60g within the range of concentrations required for gettering.

For example, the imaging device 100A satisfies the relation 1<A/B<400000, where A is the concentration of a metallic element of metallic silicide in the silicide region SR and B is the concentration of carbon in the gettering layer 60g. Alternatively, the imaging device 100A may satisfy the relation 10<A/B<7000. As shown in FIG. 6, the dark current can be effectively reduced by A/B falling within this range.

Further, for example, the imaging device 100A satisfies the relation 2<A/C<10000, where A is the concentration of a metallic element of metallic silicide in the silicide region SR and C is the concentration of oxygen in the gettering layer 60g. Alternatively, the imaging device 100A may satisfy the relation 40<A/C<200. As shown in FIG. 7, the dark current can be effectively reduced by A/C falling within this range.

A is a peak value of the concentration of a metallic element of metallic silicide in a position equivalent to the silicide region SR. Further, B is a peak value of the concentration of carbon in a position equivalent to the gettering layer 60g. Further, C is a peak value of the concentration of oxygen in a position equivalent to the gettering layer 60g. A, B, and C are measured, for example, by a SIMS analysis such as that described above.

### Position of Gettering Layer

As described above, since the impurity element of the gettering layer 60g can affect a leak current such as a dark current, a positional relationship between the gettering layer 60g and an impurity region such as the n-type impurity region 67n can affect a leak current. In the semiconductor substrate 60, a diffusion coefficient of a metal such as nickel that is used in the formation of the silicide region SR is higher than diffusion coefficients of carbon, oxygen, or other impurity elements contained in the gettering layer 60g. Since the gettering layer 60g faces the silicide region SR across the n-type impurity region 67n, the gettering layer 60g is farther away from the silicide region SR than is the n-type impurity region 67n, but the diffusion coefficient relationship causes the metal such as nickel to diffuse into the gettering layer 60g beyond the n-type impurity region 67n to be gettered. Further, for example, as shown in FIG. 4, the distance L1 between the n-type impurity region 67n and the gettering layer 60g may be longer than the distance L2 between the silicide region SR of the contact plug cp1 and the n-type impurity region 67n. Since the diffusion coefficient of the metal such as nickel is higher than the diffusion coefficients of carbon, oxygen, or other impurity elements, the metal such as nickel is likely to diffuse into the gettering layer 60g beyond the n-type impurity region 67n to be gettered. Meanwhile, since the distance L1 is long, carbon, oxygen, or other impurity elements contained in the gettering layer 60g are inhibited from diffusing into the n-type impurity region 67n. This makes it possible to reduce a leak current in the n-type impurity region 67n.

The distance L1 between the n-type impurity region 67n and the gettering layer 60g is, for example, longer than or equal to 2 μm. The distance L1 may be longer than or equal to 3 μm. Further, the distance L1 may be shorter than or equal to 10 μm, or may be shorter than or equal to 5 μm.

Further, as shown in FIG. 4, locating the n-type impurity region 67n within the epitaxial layer 60b and locating the gettering layer 60g not within the epitaxial layer 60b but within the base substrate 60a can separate the gettering layer 60g and the n-type impurity region 67n from each other. This makes it possible to reduce the effect brought about by the impurity element in the gettering layer 60g diffusing into the n-type impurity region 67n located within the epitaxial layer 60b, making it possible to reduce a leak current. Further, the n-type impurity region 67n can further reduce a leak current by being separated from the gettering layer 60g, whose crystallinity tends to be brought into disorder, and located within the epitaxial layer 60b, whose crystallinity is high.

### Modification

Next, a modification of Embodiment 1 is described. The following gives a description with a focus on points of difference from Embodiment 1, and a description of common features is omitted or simplified.

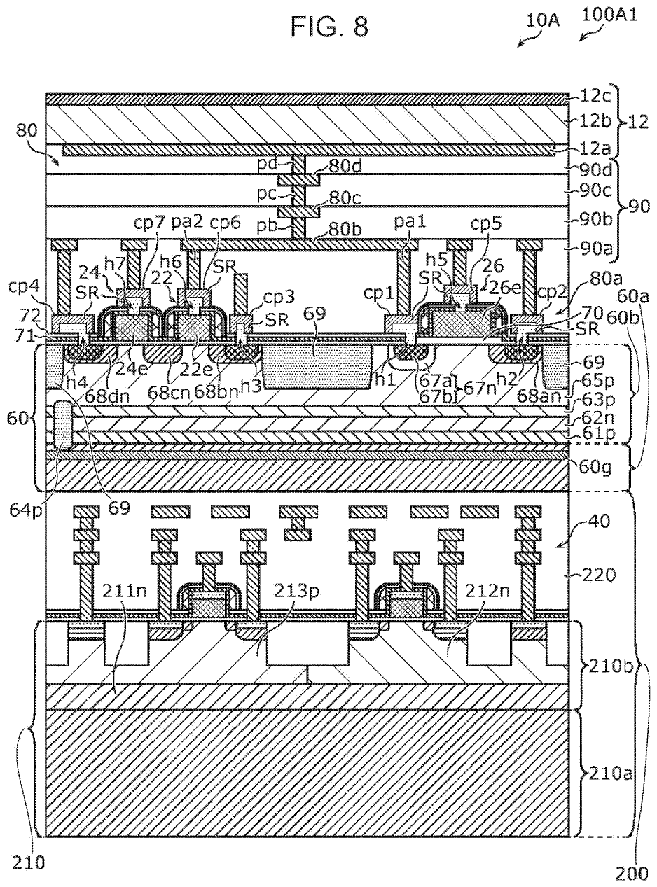

Although, in the imaging device 100A described above, the peripheral circuit 40 is placed in the peripheral region R2 of the semiconductor substrate 60, this is not intended to impose any limitation. At least part of the peripheral circuit 40 may be placed in another semiconductor substrate that is different from the semiconductor substrate 60 in which the plurality of pixels 10A are formed. That is, at least part of the peripheral circuit 40 may not be placed in the peripheral region R2. Further, in this case, the different semiconductor substrate may be stacked on the semiconductor substrate 60. FIG. 8 is a schematic cross-sectional view of a device structure of an imaging device 100A1 according to the present modification. For viewability, FIG. 8 omits hatching that indicates cross-sections of the insulating layers 70 and 72, the interlayer insulating layer 90, an interlayer insulating layer 220, and a device isolation region within a semiconductor substrate 210. Further, FIG. 8 shows transistors and wires as some circuit elements included in the peripheral circuit 40.

As shown in FIG. 8, the imaging device 100A1 may further include a peripheral circuit layer 200. The peripheral circuit layer 200 is a logic circuit chip including a semiconductor substrate 210 in which the peripheral circuit 40 is formed and the interlayer insulating layer 220 on top of the semiconductor substrate 210. Part of the peripheral circuit 40 may be formed on the semiconductor substrate 60.

On the peripheral circuit layer 200, the semiconductor substrate 60 in which a pixel 10A is formed is stacked. The semiconductor substrate 60 is stacked on the peripheral circuit layer 200, for example, after the base substrate 60a has been thinned so that the gettering layer 60g remains. A lower surface of the semiconductor substrate 60 and an upper surface of the interlayer insulating layer 220 are joined to each other. In the imaging device 100A1, for example, the thickness of the semiconductor substrate 60 is thinner than the thickness of the semiconductor substrate 210. This makes it possible to shorten a wire for connecting a circuit formed on the semiconductor substrate 60 to a circuit formed on the semiconductor substrate 210, thus reducing resistance and improving the speed of propagation of a signal from the pixel 10A. This results in making it possible to relatively reduce the influence of noise.

The semiconductor substrate 210 includes a base substrate 210a and an epitaxial layer 210b including one or more semiconductor layers formed on top of the base substrate 210a. The base substrate 210a is, for example, a p-type silicon substrate. In the example shown in FIG. 8, the epitaxial layer 210b includes an n-type semiconductor layer 211n on top of the base substrate 210a, an n-type semiconductor layer 212n on top of the n-type semiconductor layer 211n, and a p-type semiconductor layer 213p located in a region on top of the n-type semiconductor layer 211n that is different from that in which the n-type semiconductor layer 212n is located.

The peripheral circuit 40 includes a plurality of transistors including sources and drains formed in the n-type semiconductor layer 212n and the p-type semiconductor layer 213p and a wiring structure formed in the interlayer insulating layer 220.

The imaging device 100A1 can be miniaturized by the semiconductor substrate 60 being thus stacked on the peripheral circuit layer 200 in which at least part of the peripheral circuit 40 is provided.

### Embodiment 2

Next, Embodiment 2 is described. The following gives a description with a focus on points of difference from Embodiment 1, and a description of common features is omitted or simplified.

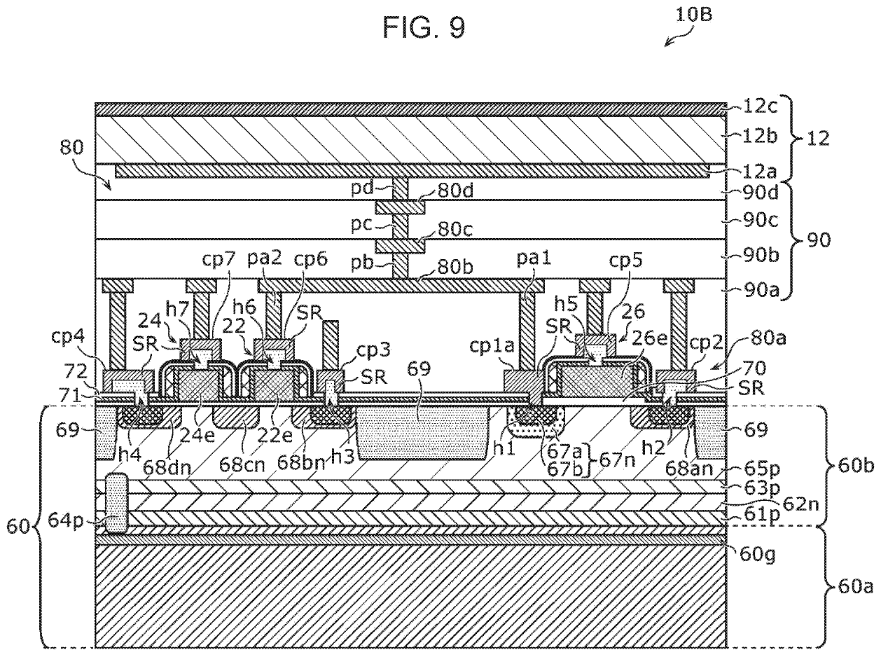

FIG. 9 is a schematic cross-sectional view of a device structure of a pixel 10B of an imaging device according to the present embodiment. For viewability, FIG. 9 omits hatching that indicates cross-sections of the insulating layers 70 and 72 and the interlayer insulating layer 90.

The imaging device according to the present embodiment has a configuration in which the pixel 10A of the imaging device 100A according to Embodiment 1 is replaced by the pixel 10B. The pixel 10B shown in FIG. 9 differs from the pixel 10A according to Embodiment 1 in that the pixel 10B includes a contact plug cp1a in place of the contact plug cp1.

Unlike the contact plugs cp2, cp3, cp4, cp5, cp6, and cp7, the contact plug cp1a includes no silicide region SR. The contact plug cp1a is formed by polysilicon doped with impurities such as n-type impurities. A prime constituent element of the contact plug cp1a is, for example, silicon. For example, the contact plug cp1a, which includes no silicide region SR, can be formed by forming the silicide region SR in the contact plugs cp2, cp3, cp4, cp5, cp6, and cp7 with the contact plug cp1a protected by a protective film. In the present embodiment, one of the contact plugs cp2, cp3, and cp4 is an example of a first plug. Further, in the present embodiment, one of the n-type impurity regions 68an, 68bn, and 68dn that is connected to the one of the contact plugs cp2, cp3, and cp4 is an example of a first impurity region. Further, in the present embodiment, the contact plug cp1a is an example of a second plug. Further, in the present embodiment, the n-type impurity region 67n is an example of a second impurity region. The plug pa1 is connected to an upper surface of the contact plug cp1a. Although not illustrated, an oxide film is formed on the upper surface and side surfaces of the contact plug cp1a, and the plug pa1 penetrates through the oxide film.

In the pixel 10B, the contact plug cp1a, which includes no silicide region SR, is connected to the n-type impurity region 67n, which is a charge accumulation region. This reduces the diffusion of the metallic impurity into the n-type impurity region 67n, making it possible to further reduce a dark current. Further, since the contact plugs cp2, cp3, cp4, cp5, cp6, and cp7 include the silicide region SR, the driving capabilities of transistors connected to these contact plugs can be enhanced. In particular, the inclusion of the silicide region SR by the contact plugs cp3, cp4, cp6, and cp7 connected to the amplifying transistor 22 and the address transistor 24 to which a pixel signal is outputted brings about a reduction in contact resistance between these contact plugs and the metal. This enables, for example, the speeding up of a pixel signal readout operation, which is directly linked to a frame rate. Further, the gettering layer 60g getters the metallic impurity that diffuses from the silicide region SR, making it possible to reduce a leak current in the semiconductor substrate 60.

Further, in the pixel 10B, the concentration of the group 14 element other than silicon in the gettering layer 60g may not be uniformly distributed when seen in a plan view, and for example, in a plan view, in a position overlapping the n-type impurity region 67n, the concentration may be lower than it is in a position not overlapping the n-type impurity region 67n. Further, in the pixel 10B, the gettering layer 60g may not be formed in the position overlapping the n-type impurity region 67n in a plan view.

In the imaging device according to the present embodiment, the semiconductor substrate 60 may be stacked on the peripheral circuit layer 200 as in the case of the imaging device 100A1.

### Embodiment 3

Next, Embodiment 3 is described. The following gives a description with a focus on points of difference from Embodiments 1 and 2, and a description of common features is omitted or simplified.

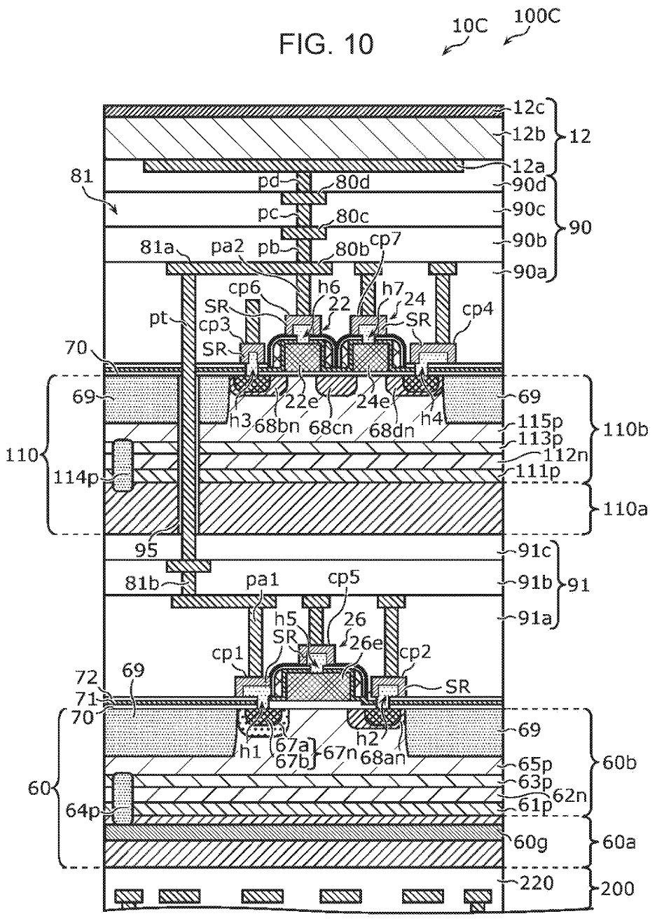

FIG. 10 is a schematic cross-sectional view of a device structure of an imaging device 100C according to the present embodiment. For viewability, FIG. 10 omits hatching that indicates cross-sections of the insulating layers 70 and 72, the interlayer insulating layer 90, an interlayer insulating layer 91, the interlayer insulating layer 220, and an insulating film 95. Further, FIG. 10 shows the device structure of the imaging device 100C above an area near an upper surface of the peripheral circuit layer 200. The peripheral circuit layer 200 is configured as described above with reference to FIG. 8.

The imaging device 100C according to the present embodiment has a configuration in which the pixel 10A of the imaging device 100A1 according to the modification of Embodiment 1 is replaced by a pixel 10C. The pixel 10C differs from the pixel 10A primarily in that the amplifying transistor 22, address transistor 24, and reset transistor 26 of the signal detection circuit 14 are separately placed on the semiconductor substrate 60 and a semiconductor substrate 110 stacked on top of the semiconductor substrate 60. The pixel 10C is identical in circuit configuration to the pixel 10A.

Specifically, as shown in FIG. 10, the pixel 10C differs from the pixel 10A in that the pixel 10C further includes the semiconductor substrate 110 and a through-silicon via pt.

As schematically shown in FIG. 10, the pixel 10C schematically includes the semiconductor substrate 60, the semiconductor substrate 110 placed above the semiconductor substrate 60, a photoelectric converter 12 placed above the semiconductor substrate 110, and a wiring structure 81. The wiring structure 81 is placed within the semiconductor substrate 110, within the interlayer insulating layer 90 formed between the photoelectric converter 12 and the semiconductor substrate 110, and within the interlayer insulating layer 91 formed between the semiconductor substrate 110 and the semiconductor substrate 60. The semiconductor substrates 60 and 110 and the interlayer insulating layers 90 and 91 are continuously formed, for example, at least all over the imaging region R1 and are shared by a plurality of the pixels 10C.

In the example shown in FIG. 10, the interlayer insulating layer 91 has a stack structure including three insulating layers, namely insulating layers 91a, 91b, and 91c. The number of insulating layers that are included in the interlayer insulating layer 91 is not limited to particular numbers. The wiring structure 81 includes the through-silicon via pt, which penetrates through the semiconductor substrate 110, and connecting structures 81a and 81b electrically connected to each other by the through-silicon via pt. The through-silicon via pt and the connecting structures 81a and 81b function as a charge accumulation region in which to accumulate signal charge generated by the photoelectric converter 12. The connecting structure 81a is located within the interlayer insulating layer 90 and electrically connects the through-silicon via pt to the gate electrode 22e and the pixel electrode 12a. The connecting structure 81b is located within the interlayer insulating layer 91 and electrically connects the through-silicon via pt to the n-type impurity region 67n. As is the case with the wiring structure 80, the wiring structure 81 includes contact plugs cp1, cp2, cp3, cp4, cp5, cp6, and cp7 and plugs, such as the plugs pa1 and the plug pa2, that are connected to these contact plugs. Further, the contact plug cp6 and the plug pa2 are part of the connecting structure 81a, and the contact plug cp1 and the plug pa1 are part of the connecting structure 81b.

In the pixel 10C, the reset transistor 26 is formed on the semiconductor substrate 60, and the amplifying transistor 22 and the address transistor 24 are formed on the semiconductor substrate 110. The wiring structure 81 electrically connects the photoelectric converter 12 to the signal detection circuit 14 formed on the semiconductor substrates 60 and 110. The reset transistor 26 is placed on the upper surface of the semiconductor substrate 60, and the amplifying transistor 22 and the address transistor 24 are placed on an upper surface of the semiconductor substrate 110. That is, the surface of the semiconductor substrate 60 on which the reset transistor 26 is placed and the surface of the semiconductor substrate 110 on which the amplifying transistor 22 and the address transistor 24 are placed do not face each other but face the same direction. The upper surface of the semiconductor substrate 60 and the upper surface of the semiconductor substrate 110 are surfaces of the semiconductor substrate 60 and the semiconductor substrate 110 that face the photoelectric converter 12.

The semiconductor substrate 110 is placed between the semiconductor substrate 60 and the photoelectric converter 12. The semiconductor substrate 110 includes a base substrate 110a and an epitaxial layer 110b including one or more semiconductor layers formed on top of the base substrate 110a. The one or more semiconductor layers included in the epitaxial layer 110b have, for example, a layer configuration of the same conductivity type as the one or more semiconductor layers included in the epitaxial layer 60b.

The base substrate 110a is, for example, a p-type silicon substrate. The impurity concentration of the base substrate 110a is, for example, equal to the impurity concentration of the base substrate 60a. Although, in the example shown in FIG. 10 no gettering layer is provided within the base substrate 110a, a gettering layer may be provided within the base substrate 110a. Further, in the example shown in FIG. 10, the epitaxial layer 110b includes a p-type semiconductor layer 111p on top of the base substrate 110a, an n-type semiconductor layer 112n on top of the p-type semiconductor layer 111p, a p-type semiconductor 113p on top of the n-type semiconductor layer 112n, a p-type semiconductor layer 115p on top of the p-type semiconductor layer 113p. The p-type semiconductor layer 111p, the p-type semiconductor 113p, and the p-type semiconductor layer 115p are semiconductor layers containing p-type impurities. The configuration of one or more semiconductor layers included in the epitaxial layer 110b is not limited to particular configurations but can be designed for any purpose. Further, at least part of portions of the semiconductor substrate 110 other than the p-type semiconductor layer 115p may be removed by thinning.

Further, in this example, the semiconductor substrate 110 includes a p-type region 114p provided between the p-type semiconductor layer 115p and the base substrate 110a in such a manner as to penetrate through the p-type semiconductor layer 111p, the n-type semiconductor layer 112n, the p-type semiconductor layer 113p. The p-type region 114p may not penetrate through the p-type semiconductor layer 113p to reach the p-type semiconductor layer 115p, as long as the p-type region 114p reaches the p-type semiconductor layer 113p. The p-type region 114p has a higher impurity concentration than do the p-type semiconductor layers 113p and 115p and electrically connects the p-type semiconductor layers 113p and 115p to the base substrate 110a.

When the imaging device 100C is in operation, the potentials of the p-type semiconductor layers 113p and 115p and the base substrate 110a are controlled via a contact (not illustrated) provided outside the imaging region R1. Further, placing the p-type semiconductor layer 115p in contact with the p-type semiconductor layer 113p makes it possible to also control the potential of the p-type semiconductor layer 115p via the p-type semiconductor layer 113p when the imaging device 100C is in operation. The p-type semiconductor layer 115p may be provided with a contact opposite to the base substrate 110a so that the potential may be controlled via the contact.

In the pixel 10C, the n-type impurity regions 67n and 68an are located within the p-type semiconductor layer 65p, and the n-type impurity regions 68bn, 68cn, and 68dn are located within the p-type semiconductor layer 115p.

The through-silicon via pt penetrates through the semiconductor substrate 110 and electrically connects the wiring layer 80b to the plug pa1. Therefore, the n-type impurity region 67n and the gate electrode 22e of the amplifying transistor 22 are electrically connected to each other via the contact plugs cp1 and cp6, the plugs pa1 and pa2, the through-silicon via pt, and the wiring layer 80b. The through-silicon via pt is formed, for example, from a metal such as copper or tungsten, polysilicon doped with impurities, a metallic compound such as a metallic nitride or a metallic oxide, or other substances.

The insulating film 95 is placed between the through-silicon via pt and the semiconductor substrate 110, and the through-silicon via pt and the semiconductor substrate 110 are not in contact with each other. The insulating film 95 is, for example, a silicon oxide film.

In the present embodiment, such a configuration causes the amplifying transistor 22 and the address transistor 24 to be provided in the p-type semiconductor layer 115p of the semiconductor substrate 110 and causes the reset transistor 26 to be provided in the p-type semiconductor layer 65p of the semiconductor substrate 60, which is different from the semiconductor substrate 110. This makes it possible to reduce pixel size in a plan view, making it possible to miniaturize the imaging device 100C. Further, since the n-type impurity region 67n, which is a charge accumulation region, is formed in the semiconductor substrate 60, in which the gettering layer 60g is provided, the gettering layer 60g brings about an effect of gettering the metallic impurity, making it possible to reduce a dark current.

In the imaging device 100C, the semiconductor substrate 110 and the semiconductor substrate 60 may be put in the opposite positions to the ones in which they are in the example described above. That is, the semiconductor substrate 60 may be placed between the semiconductor substrate 110 and the photoelectric converter 12. Further, in the imaging device 100C, at least part of the peripheral circuit 40 may be provided not in the peripheral circuit layer 200 but in at least either the semiconductor substrate 60 or the semiconductor substrate 110 in the peripheral region R2. Therefore, the imaging device 100C may not include the peripheral circuit layer 200. Further, as is the case with the pixel 10B, the pixel 10C may include a contact plug cp1a in place of the contact plug cp1.

### Embodiment 4

Next, Embodiment 4 is described. The following gives a description with a focus on points of difference from Embodiments 1 to 3, and a description of common features is omitted or simplified.

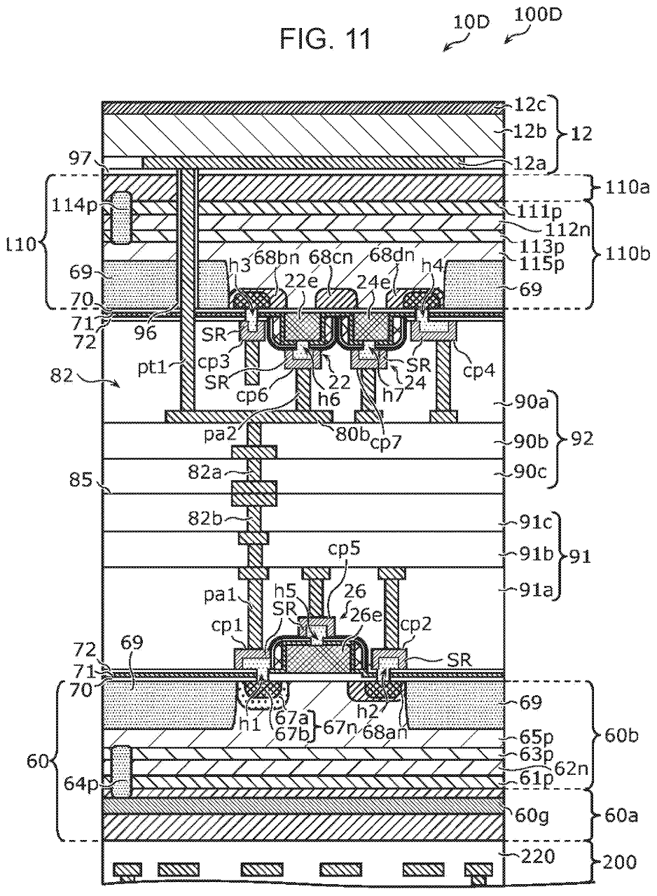

FIG. 11 is a schematic cross-sectional view of a device structure of an imaging device 100D according to the present embodiment. For viewability, FIG. 11 omits hatching that indicates cross-sections of the insulating layers 70 and 72, an insulating layer 97, the interlayer insulating layer 91, an interlayer insulating layer 92, the interlayer insulating layer 220, and an insulating film 96. Further, FIG. 11 shows the device structure of the imaging device 100D above an area near an upper surface of the peripheral circuit layer 200. The peripheral circuit layer 200 is configured as described above with reference to FIG. 8.

The imaging device 100D according to the present embodiment has a configuration in which the pixel 10C of the imaging device 100C according to Embodiment 3 is replaced by a pixel 10D. The pixel 10D differs from the pixel 10C primarily in that the orientation of the semiconductor substrate 110 is turned upside down. The pixel 10D is identical in circuit configuration to the pixel 10A.

As schematically shown in FIG. 11, the pixel 10D schematically includes the semiconductor substrate 60, the semiconductor substrate 110 placed above the semiconductor substrate 60, a photoelectric converter 12 placed above the semiconductor substrate 110, and a wiring structure 82. The wiring structure 82 is placed within the semiconductor substrate 110, within the insulating layer 97 formed between the photoelectric converter 12 and the semiconductor substrate 110, and within the interlayer insulating layers 91 and 92 formed between the semiconductor substrate 110 and the semiconductor substrate 60. The semiconductor substrates 60 and 110 and the interlayer insulating layers 91 and 92 are continuously formed, for example, at least all over the imaging region R1 and are shared by a plurality of the pixels 10D.

In the example shown in FIG. 11, the interlayer insulating layer 92 has a stack structure including three insulating layers, namely insulating layers 90a, 90b, and 90c. The number of insulating layers that are included in the interlayer insulating layer 92 is not limited to particular numbers. The wiring structure 82 includes a through-silicon via pt1 that penetrates through the semiconductor substrate 110 and connecting structures 82a and 82b connected to each other at a junction surface 85. The through-silicon via pt1 and the connecting structures 82a and 82b function as a charge accumulation region in which to accumulate signal charge generated by the photoelectric converter 12. The connecting structure 82a is located within the interlayer insulating layer 92 and electrically connects the through-silicon via pt1, the connecting structure 82b, and the gate electrode 22e to one another. The connecting structure 82b is located within the interlayer insulating layer 91 and electrically connects the connecting structure 82a to the n-type impurity region 67n. As is the case with the wiring structure 80, the wiring structure 82 includes contact plugs cp1, cp2, cp3, cp4, cp5, cp6, and cp7 and plugs that are connected to these contact plugs. Further, the contact plug cp6 and the plug pa2 are part of the connecting structure 82a, and the contact plug cp1 and the plug pa1 are part of the connecting structure 82b.

At the junction surface 85, the insulating materials of the interlayer insulating layers 91 and 92 and the metal wires of the connecting structures 82a and 82b form metal-dielectric hybrid junctions. The junction surface 85 is continuously formed, for example, at least all over the imaging region R1.

In the pixel 10D, as in the case of the pixel 10C, the reset transistor 26 is formed on the semiconductor substrate 60, and the amplifying transistor 22 and the address transistor 24 are formed on the semiconductor substrate 110. The wiring structure 82 electrically connects the photoelectric converter 12 to the signal detection circuit 14 formed on the semiconductor substrates 60 and 110.

The order of stacking in the semiconductor substrate 110 in the pixel 10D is the upside-down opposite of the order of stacking in the semiconductor substrate 110 in the pixel 10C. That is, while the pixel 10C is configured such that the epitaxial layer 110b is located above the base substrate 110a and the p-type semiconductor layer 115p is the uppermost layer in the semiconductor substrate 110, the pixel 10D is configured such that the epitaxial layer 110b is located below the base substrate 110a and the p-type semiconductor layer 115p is the lowermost layer in the semiconductor substrate 110. In the pixel 10D, the photoelectric converter 12 is placed on top of the insulating layer 97 on the upper surface of the semiconductor substrate 110.

In the pixel 10D, the reset transistor 26 is placed in the upper surface of the semiconductor substrate 60, and the amplifying transistor 22 and the address transistor 24 are placed in a lower surface of the semiconductor substrate 110. That is, the surface of the semiconductor substrate 60 in which the reset transistor 26 is placed and the surface of the semiconductor substrate 110 in which the amplifying transistor 22 and the address transistor 24 are placed face each other. The lower surface of the semiconductor substrate 110 is a surface of the semiconductor substrate 110 that faces away from the photoelectric converter 12.

The through-silicon via pt1 penetrates through the semiconductor substrate 110 and electrically connects the wiring layer 80b to the pixel electrode 12a. The through-silicon via pt1 functions as a charge accumulation region in which to accumulate signal charge generated by the photoelectric converter 12. The n-type impurity region 67n and the gate electrode 22e of the amplifying transistor 22 are electrically connected to each other via the contact plugs cp1 and cp6, the plugs pa1 and pa2, and the wiring layer 80b without the through-silicon via pt1. The through-silicon via pt1 is formed, for example, from a metal such as copper or tungsten, polysilicon doped with impurities, a metallic compound such as a metallic nitride or a metallic oxide, or other substances.

The insulating film 96 is placed between the through-silicon via pt1 and the semiconductor substrate 110, and the through-silicon via pt1 and the semiconductor substrate 110 are not in contact with each other. The insulating film 96 is, for example, a silicon oxide film.

Such a configuration causes the amplifying transistor 22 and the address transistor 24 to be provided in one semiconductor substrate and causes the reset transistor 26 to be provided in another semiconductor substrate. This makes it possible to reduce pixel size, making it possible to miniaturize the imaging device 100D. Further, since the n-type impurity region 67n, in which to accumulate signal charge, is provided in the semiconductor substrate 60, which is farther away from the photoelectric converter 12 than is the semiconductor substrate 110, electric charge is inhibited from being generated by light not absorbed by the photoelectric converter 12 falling on the n-type impurity region 67n. This makes it possible to make the imaging device 100D lower in noise.

Further, in the pixel 10D, the surface of the semiconductor substrate 60 in which the reset transistor 26 is placed and the surface of the semiconductor substrate 110 in which and the amplifying transistor 22 and the address transistor 24 are placed face each other. Therefore, even in a case where the amplifying transistor 22 and the reset transistor 26 are connected to each other by the connecting structures 82a and 82b, the amplifying transistor 22 and the reset transistor 26 can be connected to each other without the through-silicon via pt1, which penetrates through the semiconductor substrate 110. This makes it possible to shorten the connecting structures 82a and 82b. Therefore, a parasitic capacitance between the connecting structures 82a and 82b of adjacent pixels 10D can be reduced. This results in making it possible to reduce the capacitances of the connecting structures 82a and 82b, which function as a charge accumulation region, thus bringing about a greater change in potential due to the accumulation of signal charge and increasing a gain of conversion by the charge accumulation region. This makes it possible to reduce the influence of noise by amplifying a signal corresponding to electric charge generated by photoelectric conversion, making it possible to make the imaging device 100D lower in noise.

In the imaging device 100D, the semiconductor substrate 110 and the semiconductor substrate 60 may be put in the opposite positions to the ones in which they are in the example described above. That is, the semiconductor substrate 60 may be placed between the semiconductor substrate 110 and the photoelectric converter 12, and the semiconductor substrate 60 may be put in the opposite up-down orientation to the one it is in the pixel 10C. Further, in the imaging device 100D, at least part of the peripheral circuit 40 may be provided not in the peripheral circuit layer 200 but in at least either the semiconductor substrate 60 or the semiconductor substrate 110 in the peripheral region R2. Therefore, the imaging device 100D may not include the peripheral circuit layer 200. Further, as is the case with the pixel 10B, the pixel 10D may include a contact plug cp1a in place of the contact plug cp1.

### Embodiment 5

Next, Embodiment 5 is described. The following gives a description with a focus on points of difference from Embodiments 1 to 4, and a description of common features is omitted or simplified.

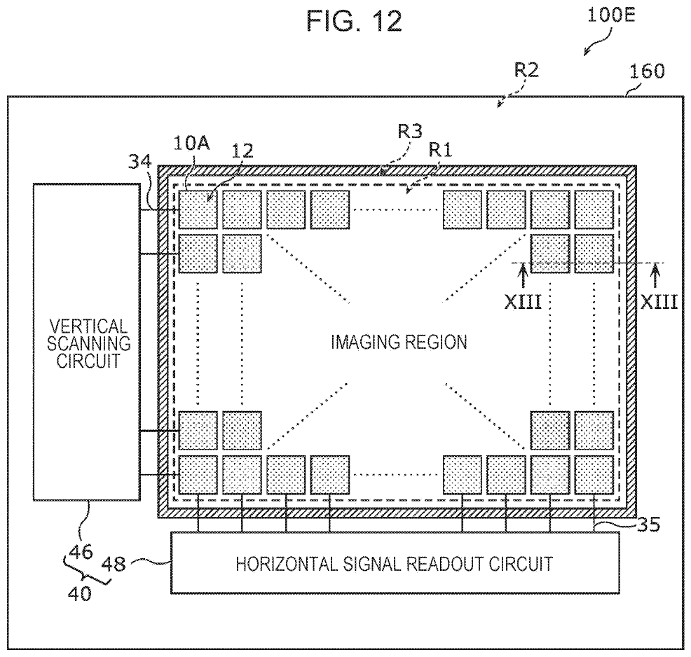

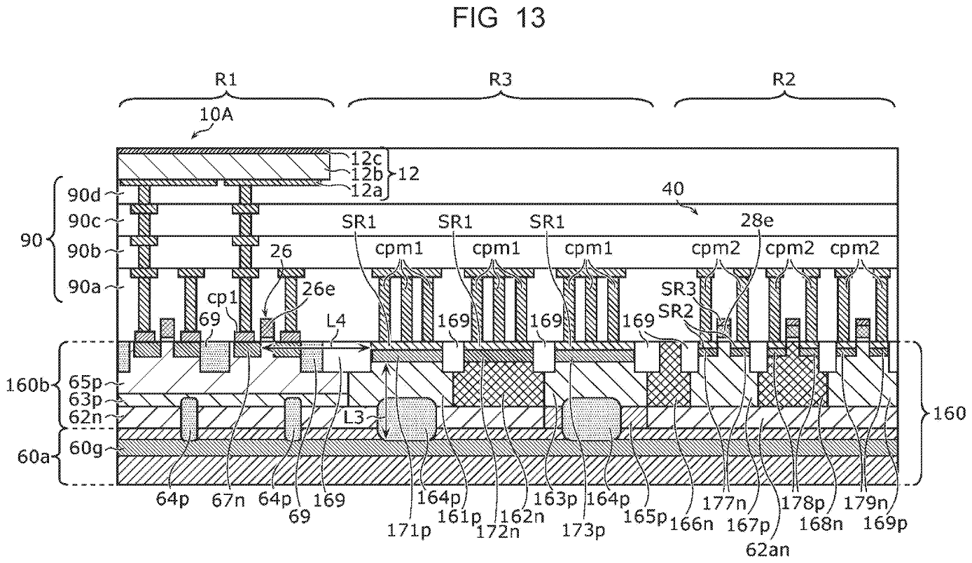

FIG. 12 is a diagram showing a configuration of an imaging device 100E according to the present embodiment. FIG. 13 is a schematic cross-sectional view of a device structure of the imaging device 100E according to the present embodiment. FIG. 13 shows a cross-section taken along line XIII-XIII in FIG. 12. It should be noted that FIG. 13 omits to illustrate a detailed device structure of a pixel 10A formed in the imaging region R1. The device structure of the pixel 10A is as described above with reference to FIG. 4. Further, for viewability, FIG. 13 omits hatching that indicates cross-sections of the interlayer insulating layer 90 and a device isolation region 169.

As shown in FIGS. 12 and 13, the imaging device 100E according to the present embodiment has a configuration in which the semiconductor substrate 60 of the imaging device 100A is replaced by a semiconductor substrate 160. The semiconductor substrate 60 and the semiconductor substrate 160 differ from each other primarily in that a substrate potential supply region R3 is present between the imaging region R1 where the plurality of pixels 10A are placed and the peripheral region R2 where the peripheral circuit 40 is placed and an impurity region including a silicide region SR1 is placed in the substrate potential supply region R3. Further, the imaging device 100E includes a plurality of contact plugs cpm1 and a plurality of contact plugs cpm2. The plurality of contact plugs cpm1 and the plurality of contact plugs cpm2 are formed, for example, from a metal such as copper or tungsten, a metallic compound such as a metallic nitride or a metallic oxide, or other substances.

As shown in FIG. 12, the substrate potential supply region R3 is placed outside the imaging region R1 and surrounds the imaging region R1. In the substrate potential supply region R3, it is possible to supply a voltage for controlling a potential of a well and a semiconductor layer of the semiconductor substrate 160. The substrate potential supply region R3 may not surround the imaging region R1, as long as the substrate potential supply region R3 is placed outside the imaging region R1. The substrate potential supply region R3 is placed, for example, along at least one of four outer sides of the imaging region R1.

As shown in FIG. 13, the semiconductor substrate 160 includes a base substrate 60a and an epitaxial layer 160b including one or more semiconductor layers formed on top of the base substrate 60a. The base substrate 60a and the gettering layer 60g located within the base substrate 60a are continuously formed, for example, all over the semiconductor substrate 160.

Further, in the example shown in FIG. 13, the epitaxial layer 160b includes, in the imaging region R1, an n-type semiconductor layer 62n on top of the base substrate 60a, a p-type semiconductor layer 63p on top of the n-type semiconductor layer 62n, a p-type semiconductor layer 165p, and a p-type semiconductor layer 65p on top of the p-type semiconductor layer 63p, and a p-type region 64p. Further, the epitaxial layer 160b includes, in the substrate potential supply region R3, an n-type semiconductor layer 62n on top of the base substrate 60a, a p-type semiconductor layer 165p located in a region on top of the base substrate 60a that is different from that in which the n-type semiconductor layer 62n is located, a p-type semiconductor layer 161p on top of the n-type semiconductor layer 62n, an n-type semiconductor layer 162n located in a region on top of the n-type semiconductor layer 62n that is different from that in which the p-type semiconductor layer 161p is located, a p-type semiconductor layer 163p on top of the p-type semiconductor layer 165p, and a p-type region 164p electrically connecting the base substrate 60a to the p-type semiconductor layer 161p or 163p. Further, the epitaxial layer 160b includes, in the peripheral region R2, an n-type semiconductor layer 62an on top of the base substrate 60a as well as an n-type semiconductor layer 166n, a p-type semiconductor layer 167p, an n-type semiconductor layer 168n, and a p-type semiconductor layer 169p that are located in different regions on top of the n-type semiconductor layer 62an. The epitaxial layer 160b may further include a p-type semiconductor layer 61p on top of the base substrate 60a.

The semiconductor substrate 160 further includes p-type impurity regions 171p, 173p, and 178p, n-type impurity regions 172n, 177n, and 179n, and the device isolation region 169. The p-type impurity regions 171p, 173p, and 178p and the n-type impurity regions 172n, 177n, and 179n are located within the epitaxial layer 160b and are separated from the gettering layer 60g. Further, in a plan view, the p-type impurity regions 171p, 173p, and 178p and the n-type impurity regions 172n, 177n, and 179n are placed in positions that are difference from those of the impurity regions, such as the n-type impurity region 67n, that are included in the pixel 10A. The device isolation region 169 is located within the epitaxial layer 160b and electrically separate the impurity regions or the transistors within the epitaxial layer 160b. As the device separation region 169, for example, an STI is used.

As shown in FIG. 13, the p-type impurity region 171p, the n-type impurity region 172n, and the p-type impurity region 173p are located within the p-type semiconductor layer 161p, the n-type semiconductor layer 162n, and the p-type semiconductor layer 163p and disposed to be exposed at upper surfaces of the p-type semiconductor layer 161p, the n-type semiconductor layer 162n, and the p-type semiconductor layer 163p, respectively. The p-type impurity region 171p, the n-type impurity region 172n, and the p-type impurity region 173p are higher in impurity concentration than the p-type semiconductor layer 161p, the n-type semiconductor layer 162n, and the p-type semiconductor layer 163p, respectively. The p-type impurity region 171p, the n-type impurity region 172n, and the p-type impurity region 173p are disposed to surround the imaging region R1, for example, in a plan view.

The p-type impurity region 171p, the n-type impurity region 172n, and the p-type impurity region 173p each include the silicide region SR1. The silicide region SR1 is, for example, a silicide layer containing metallic silicide formed by depositing a metal on surfaces of the p-type impurity region 171p, the n-type impurity region 172n, and the p-type impurity region 173p and then causing the metal and polysilicon to react with each other. The silicide region SR1 is formed on at least upper surfaces of the p-type impurity region 171p, the n-type impurity region 172n, and the p-type impurity region 173p.

In the silicide region SR1, the p-type impurity region 171p, the n-type impurity region 172n, and the p-type impurity region 173p each make contact with a plurality of contact plugs cpm1 that are examples of plugs. The base substrate 60a and the p-type semiconductor layer 65p have their potentials controlled via the plurality of contact plugs cpm1, the p-type impurity region 171p, and the p-type impurity region 173p. Further, the n-type semiconductor layer 62n has its potential controlled via the plurality of contact plugs cpm1 and the n-type impurity region 172n. Contact between the p-type impurity region 171p and the plurality of contact plugs cpm1, between the n-type impurity region 172n and the plurality of contact plugs cpm1, and between the p-type impurity region 173p and the plurality of contact plugs cpm1 brings about a reduction in contact resistance, making stable potential control possible.

In the substrate potential supply region R3, the gettering layer 60g faces the plurality of contact plugs cpm1 across the p-type impurity region 171p, the n-type impurity region 172n, and the p-type impurity region 173p. A metallic impurity from the silicide region SR1 is gettered by the gettering layer 60g. This makes it hard for the metallic impurity to diffuse into the imaging region R1, making it possible to reduce a dark current.

Further, the distance L3 between the silicide region SR1 of the p-type impurity region 171p closest to the imaging region R1 and the gettering layer 60g is shorter than the distance L4 between the silicide region SR1 and the n-type impurity region 67n closest to the substrate potential supply region R3. This makes it likely that the metallic impurity is gettered by the gettering layer 60g before reaching the n-type impurity region 67n. This further reduces the diffusion of the metallic impurity into the n-type impurity region 67n, making it possible to further reduce a dark current. In the present embodiment, the n-type impurity region 67n is an example of a first impurity region. The p-type impurity region 171p is an example of a second impurity region. The gettering layer 60g is an example of a third impurity region.

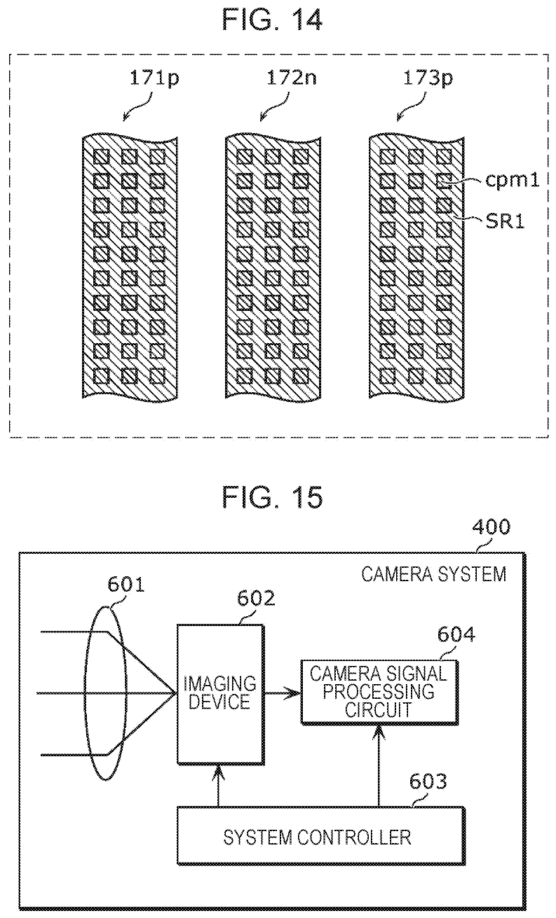

FIG. 14 is a plan view of the silicide region SR1 as seen in a plan view in the substrate potential supply region R3. For viewability, FIG. 14 applies the same hatching to the components shown in the plan view as that applied to the components shown in the cross-section of FIG. 13. As shown in FIG. 14, the p-type impurity region 171p, the n-type impurity region 172n, and the p-type impurity region 173p, which include the silicide region SR1, extend in stripes. Further, the plurality of contact plugs cpm1 are arranged in a plurality of columns on the silicide region SR1 along a direction in which the silicide region SR1 extends in stripes. Since the plurality of contact plugs cpm1 are thus arranged in the plurality of columns and connected to the silicide region SR1, the resistance for supplying a potential to the semiconductor substrate 160 can be further reduced. Further, since the substrate potential supply region R3, in which the silicide region SR1 is placed, is located between the imaging region R1 and the peripheral region R2, the plurality of contact plugs cpm1, which are arranged in the plurality of columns, make it possible to effectively suppress electrostatic coupling between the peripheral circuit 40 and the circuit of the pixel 10A.

As shown in FIG. 13, the n-type impurity region 177n, the p-type impurity region 178p, and the n-type impurity region 179n are located within the p-type semiconductor layer 167p, the n-type semiconductor layer 168n, and the p-type semiconductor layer 169p and disposed to be exposed at upper surfaces of the p-type semiconductor layer 167p, the n-type semiconductor layer 168n, and the p-type semiconductor layer 169p, respectively. The n-type impurity region 177n, the p-type impurity region 178p, and the n-type impurity region 179n are each a source or drain of a transistor included in the peripheral circuit 40.

The n-type impurity region 177n, the p-type impurity region 178p, and the n-type impurity region 179n each include a silicide region SR2. The silicide region SR2 is, for example, a silicide layer containing metallic silicide formed by depositing a metal on surfaces of the n-type impurity region 177n, the p-type impurity region 178p, and the n-type impurity region 179n and then causing the metal and polysilicon to react with each other. The silicide region SR2 is formed on at least upper surfaces of the n-type impurity region 177n, the p-type impurity region 178p, and the n-type impurity region 179n.

In the silicide region SR2, the n-type impurity region 177n, the p-type impurity region 178p, and the n-type impurity region 179n each make contact with a contact plug cpm2. This brings about a reduction in contact resistance between the n-type impurity region 177n and the contact plug cpm2, between the p-type impurity region 178p and the contact plug cpm2, and between the n-type impurity region 179n and the contact plug cpm2. This can bring about improvement in driving capability of a transistor of the peripheral circuit 40 that includes the n-type impurity region 177n, the p-type impurity region 178p, or the n-type impurity region 179n as its source or drain. Further, a gate electrode 28e of a transistor included in the peripheral circuit 40 includes a silicide region SR3 on at least an upper surface thereof. This can also bring about improvement in driving capability of a transistor of the peripheral circuit 40.

In the peripheral region R2, the gettering layer 60g faces the plurality of contact plugs cpm2 across the n-type impurity region 177n, the p-type impurity region 178p, and the n-type impurity region 179n. Further, the gettering layer 60g faces the gate electrode 28e across the p-type semiconductor layer 167p, the n-type semiconductor layer 168n, and the p-type semiconductor layer 169p. Metallic impurities from the silicide regions SR2 and SR3 are gettered by the gettering layer 60g. This makes it hard for the metallic impurities to diffuse into the imaging region R1, making it possible to reduce a dark current.

The plurality of pixels that the imaging device 100E includes are not limited to pixels 10A. The plurality of pixels that the imaging device 100E includes are not limited to particular pixels as long as they include impurity regions functioning as charge accumulation regions and may be, for example, the aforementioned pixels 10B, 10C, or 10D.

### Embodiment 6

Next, Embodiment 6 is described. Embodiment 6 describes a camera system including an imaging device according to the present disclosure.

FIG. 15 is a block diagram showing an example of a configuration of a camera system 400 according to the present embodiment.

As shown in FIG. 15, the camera system 400 according to the present embodiment includes a lens optical system 601, an imaging device 602, a system controller 603, and a camera signal processing circuit 604. The camera system 400 can be, for example, a smartphone, a digital camera, a video camera, an on-board camera, or other cameras.

The lens optical system 601 condenses light onto an imaging surface of the imaging device 602. The lens optical system 601 may include, for example, an autofocus lens, a lens group including a zoom lens, and a diaphragm. As the imaging device 602, for example, the imaging device according to any of Embodiments 1 to 5 described above.

The system controller 603 exercises overall control of the camera system 400. The system controller 603 is, for example, a semiconductor integrated circuit, and a specific example thereof is a CPU (central processing unit).

The camera signal processing circuit 604 has a function of processing an output signal from the imaging device 602. The camera signal processing circuit 604 receives output data from the imaging device 602 and performs processes such as gamma correction, color interpolation, spatial interpolation, and auto white balance. The camera signal processing circuit 604 is, for example, a DSP (digital signal processor). The imaging device 602 and the camera signal processing circuit 604 may be implemented as a signal semiconductor device. The semiconductor device can be, for example, a so-called SoC (system on a chip). Such a configuration makes it possible to further miniaturize an electronic device including the imaging device 602 as part thereof.

The camera system 400 according to the present embodiment, which uses as the imaging device 602 the imaging device according to any of Embodiments 1 to 5 described above, can achieve a low-noise camera system with a reduced leak current.

### Other Embodiments

While the foregoing has described an imaging device and a camera system according to the present disclosure with reference to embodiments, the present disclosure is not intended to be limited to these embodiments. Applications to the embodiments of various modifications conceived of by persons skilled in the art and other embodiments constructed by combining some constituent elements in the embodiments are encompassed in the scope of the present disclosure without departing from the spirit of the present disclosure.

For example, although, in each of the foregoing embodiments, the n-type impurity region 67n serves as the source or drain of the reset transistor 26, this is not intended to impose any limitation. For example, as is the case with an imaging device disclosed in International Publication No. 2020/189169, the imaging device according to the present disclosure may not include the reset transistor 26 and may be configured such that the n-type impurity region 67n is reset via the photoelectric converter 12.

For example, although, in each of the foregoing embodiments, the imaging device has the feedback circuit 16, this is not intended to impose any limitation. The imaging device according to the present disclosure may not have the feedback circuit 16 and may be configured such that a reset voltage is supplied from a voltage supply circuit to a charge accumulation region via the reset transistor 26.

For example, although, in each of the foregoing embodiments, the photoelectric converter 12 of each pixel includes the pixel electrode 12a, the transparent electrode 12c, and the photoelectric conversion layer 12b, this is not intended to impose any limitation. The photoelectric converter of each pixel may be a photodiode formed on a semiconductor substrate. Further, each pixel may include a photoelectric converter 12 and a photodiode as a plurality of photoelectric converters.

For example, although, in each of the foregoing embodiments, the gettering layer 60g is located within the base substrate 60a, this is not intended to impose any limitation. The gettering layer 60g may be located within the epitaxial layer 60b or 160b.

Further, in each of the foregoing embodiments, the conductivity types and configurations of layers and impurity regions in each semiconductor substrate are merely examples. For example, some or all of the layers and impurity regions within each semiconductor substrate may be configured to be opposite in conductivity type to those described above. Further, for example, each semiconductor substrate may not all of the layers and impurity regions or may include at least either layers or impurity regions other than the aforementioned layers and impurity regions.

Further, each of the foregoing embodiments can be subjected to various alterations, substitutions, additions, omissions, or other changes within the scope of the claims or the scope of equivalents thereof.

An imaging device according to the present disclosure is useful, for example, in an image sensor, a digital camera, or other devices. An imaging device according to the present disclosure can be used in a camera for medical use, a camera for use in a robot, a security camera, a camera that is mounted on a vehicle for use, or other cameras.

What is claimed is:

1. An imaging device comprising:
a photoelectric converter that converts light into electric charge;
a semiconductor substrate including a first impurity region and a second impurity region; and
a first plug that is connected to the first impurity region and that includes a silicide region,
wherein
either the first impurity region or the second impurity region is a charge accumulation region that is electrically connected to the photoelectric converter, and
the semiconductor substrate includes, in a position that faces the silicide region across the first impurity region, a third impurity region containing a group 14 element other than silicon.

2. The imaging device according to claim 1, wherein the first impurity region is the charge accumulation region.

3. The imaging device according to claim 1, further comprising a second plug that is connected to the second impurity region and that includes no silicide region,
wherein the second impurity region is a charge accumulation region.

4. The imaging device according to claim 1, wherein a distance between the first impurity region and the third impurity region is longer than a distance between the silicide region and the first impurity region.

5. The imaging device according to claim 1, wherein
the third impurity region contains carbon, and
the relation 1<A/B<400000 is satisfied,
where A represents a concentration of a metallic element of metallic silicide in the silicide region in units of atoms/cm³; and B represents a concentration of carbon in the third impurity region in units of atoms/cm³.

6. The imaging device according to claim 5, wherein the relation 10<A/B<7000 is satisfied.

7. The imaging device according to claim 1, wherein
the third impurity region contains the group 14 element and oxygen, and
the relation 2<A/C<10000 is satisfied,
where A represents a concentration of a metallic element of metallic silicide in the silicide region in units of atoms/cm³; and C represents a concentration of oxygen in the third impurity region in units of atoms/cm³.

8. The imaging device according to claim 7, wherein the relation 40<A/C<200 is satisfied.

9. The imaging device according to claim 1, wherein
the semiconductor substrate includes a base substrate and an epitaxial layer on top of the base substrate,
the first impurity region and the second impurity region are located within the epitaxial layer, and
the third impurity region is located within the base substrate.

10. The imaging device according to claim 1, wherein
the semiconductor substrate includes an imaging region where a plurality of pixels each including the photoelectric converter, the first impurity region, the second impurity region, and a first plug are arranged, and
the third impurity region is continuously placed all over the imaging region.

11. The imaging device according to claim 1, wherein the third impurity region is continuously placed all over the semiconductor substrate.

12. An imaging device comprising:
a photoelectric converter that converts light into electric charge;
a semiconductor substrate including a first impurity region that is electrically connected to the photoelectric converter and a second impurity region that is placed in a position different from that of the first impurity region in a plan view and that includes a silicide region; and
a plug that is connected to the silicide region of the second impurity region,
wherein
the semiconductor substrate includes, in a position that faces the plug across the second impurity region, a third impurity region containing a group 14 element other than silicon,
the second impurity region and the third impurity region are separate from each other, and
a distance between the silicide region and the third impurity region is shorter than a distance between the silicide region and the first impurity region.
